(19) United States
(12) Patent Application Publication
(10) Pub. No.: US 2024/0213333 A1
(43) Pub. Date: Jun. 27, 2024

(54) III-N DEVICE WITH PLANARIZED TOPOLOGICAL STRUCTURE

(71) Applicant: Texas Instruments Incorporated, Dallas, TX (US)

(72) Inventors: Fuchao Wang, Plano, TX (US); Bill Wofford, Sunnyvale, TX (US); Jonathan R Garrett, Garland, TX (US); Ebenezer Eshun, Frisco, TX (US); Jungwoo Joh, Allen, TX (US)

(21) Appl. No.: 18/145,625

(22) Filed: Dec. 22, 2022

(51) Int. Cl. H01L 29/40; H01L 21/02; H01L 21/3105; H01L 23/495; H01L 29/20; H01L 29/66; H01L 29/778

(52) U.S. Cl. CPC H01L 29/408; H01L 21/0217; H01L 21/02274; H01L 21/31053; H01L 23/4952; H01L 23/49562; H01L 29/2003; H01L 29/66462; H01L 29/7786

(57) ABSTRACT

A microelectronic device includes a III-N semiconductor layer having a top surface with at least one topological structure in the III-N semiconductor layer. The topological structure may be an opening in the III-N semiconductor layer or a protrusion of the III-N semiconductor layer. The microelectronic device also includes a liner including silicon nitride on the topological structure, contacting the III-N semiconductor layer. The microelectronic device further includes a fill material including silicon nitride on the topological structure on the liner. A top surface of the fill material is planar and parallel to the top surface of the III-N semiconductor layer adjacent to the topological structure.

### TECHNICAL FIELD

This disclosure relates to the field of III-N semiconductor devices. More particularly, but not exclusively, this disclosure relates to topological structures in III-N semiconductor devices.

### BACKGROUND

III-N semiconductor devices often have topography, such as gates or openings in the III-N semiconductor material. The topography hinders fabrication operations such as photolithography and etching.

### SUMMARY

The present disclosure introduces a microelectronic device including a III-N semiconductor layer having a top surface with a topological structure of the III-N semiconductor layer extending to the top surface of the III-N semiconductor layer. The microelectronic device also includes a liner including silicon nitride on the topological structure, contacting the III-N semiconductor layer. The microelectronic device further includes a fill material on the topological structure on the liner. The fill material includes silicon nitride. A top surface of the fill material is planar and parallel to the top surface of the III-N semiconductor layer adjacent to the topological structure.

### BRIEF DESCRIPTION OF THE FIGURES

FIG. 1A through FIG. 1S are cross-sections of an example microelectronic device depicted in stages of a method of formation.

FIG. 2 is a cross section of another example microelectronic device having topological structures.

FIG. 3 is a top view of a multi-chip module including the microelectronic device of FIG. 2 and a separate signal processing device.

FIG. 4A through FIG. 4I are cross sections of the microelectronic device of FIG. 2, depicted in stages of an example method of formation.

FIG. 5 is a cross section of an example microelectronic device that includes topological structures and passive components.

FIG. 6 is a cross section of an example microelectronic device that includes a topological structure and a passive component.

FIG. 7A and FIG. 7B are a top view and a cross section, respectively, of a further example microelectronic device having topological structures in a III-N semiconductor layer.

FIG. 8 is a cross section of a further example microelectronic device having topological structures.

FIG. 9 is a cross section of a further example microelectronic device having topological structures.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A microelectronic device includes a III-N semiconductor layer having a top surface. The III-N semiconductor layer has at least one topological structure extending to the top surface. The topological structure may be a protrusion or an opening, by way of example. A liner that includes silicon nitride is formed on the top surface of the III-N semiconductor layer, extending onto the topological structure. A fill material that includes primarily silicon nitride is formed on the liner, extending over the topological structure. The fill material is planarized, so that a top surface of the fill material is planar and parallel to the top surface of the III-N semiconductor layer adjacent to the topological structure.

Planarity of the top surface of the fill material may enable forming more uniform layers of photoresist with more repeatable thicknesses than would be practical without the planarized fill material. Planarity of the top surface of the fill material may also enable forming more uniform layers of conductors and dielectrics with more repeatable thicknesses than would be practical without the planarized fill material. Thus, planarity of the top surface of the fill material may enable subsequent formation of components in the microelectronic device with features smaller than a vertical dimension of the topological structure, advantageously enabling more complex components and/or a greater quantity of components in the microelectronic device.

It is noted that terms such as top, bottom, over, above, and under may be used in this disclosure. These terms should not be construed as limiting the position or orientation of a structure or element, but should be used to provide spatial relationship between structures or elements.

For the purposes of this disclosure, the term “instant top surface” of a microelectronic device refers to a top surface of the microelectronic device which exists at the particular step being disclosed. The instant top surface may change from step to step in the formation of the microelectronic device.

For the purposes of this disclosure, the terms “lateral” and “laterally” refer to a direction parallel to a plane of the top surface of the III-N semiconductor layer adjacent to the topological structure(s). Similarly, the term “vertical” refers to a direction perpendicular to the plane of the instant top surface of the III-N semiconductor layer adjacent to the topological structure(s).

For the purposes of this disclosure, the term “conductive” is to be interpreted as “electrically conductive.” The term “conductive” refers to materials and structures capable of supporting a steady electrical current, that is, direct current (DC).

For the purposes of this disclosure, a structure or component that is disclosed as including “primarily” a substance has more than 50 percent, by weight, of that substance. For example, an interconnect that is disclosed to include primarily aluminum has more than 50 percent, by weight, of the element aluminum.

For the purposes of this description, the term “III-N” refers to semiconductor materials in which group III elements, that is, aluminum, gallium, and indium, and possibly boron, provide a portion of the atoms in the semiconductor material and nitrogen atoms provide another portion of the atoms in the semiconductor material. Examples of III-N semiconductor materials are gallium nitride, boron gallium nitride, aluminum gallium nitride, indium nitride, and indium aluminum gallium nitride. Terms describing elemental formulas of materials do not imply a particular stoichiometry of the elements. For the purposes of this description, the term GaN FET refers to a field effect transistor which includes III-N semiconductor materials.

For the purposes of this description, the term “damascene structure” refers to a conductive structure formed in a hole or trench in a dielectric layer, with a barrier sublayer along sides and a bottom of the hole or trench, and a fill metal on the barrier sublayer that fills the hole or trench. A damascene structure may include an adhesion sublayer between the liner sublayer and the dielectric layer. Contacts and vias may have titanium nitride liner sublayers and tungsten fill metal. Copper damascene interconnects and vias may have tantalum nitride or titanium nitride liner sublayers and copper fill metal. Other damascene structures may have cobalt fill metal. The term “damascene process” refers to a sequence that includes forming the hole or trench in the dielectric layer, forming a liner layer on the dielectric layer, extending into the hole or trench, and forming a fill metal liner layer. The damascene process further includes removing fill metal layer and the liner layer over the dielectric layer outside of the hole or trench by a chemical mechanical polish (CMP) operation.

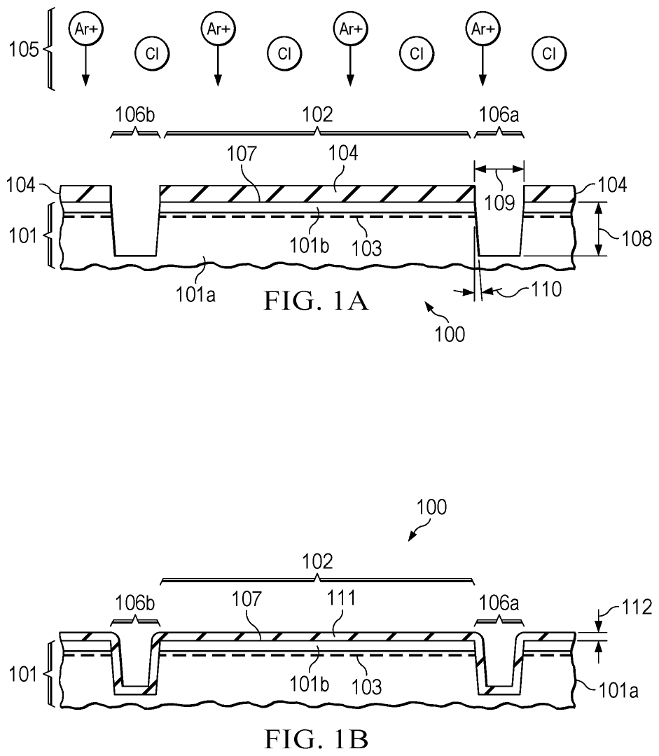

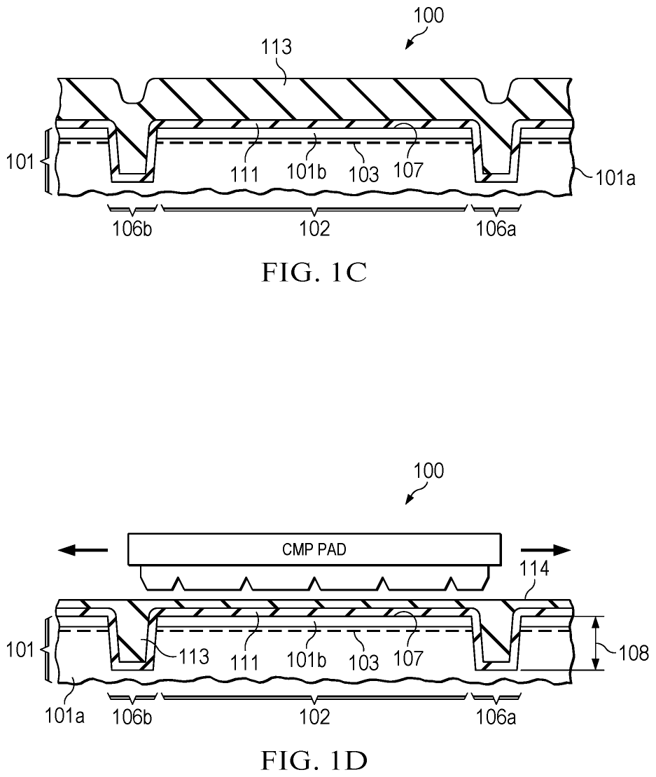

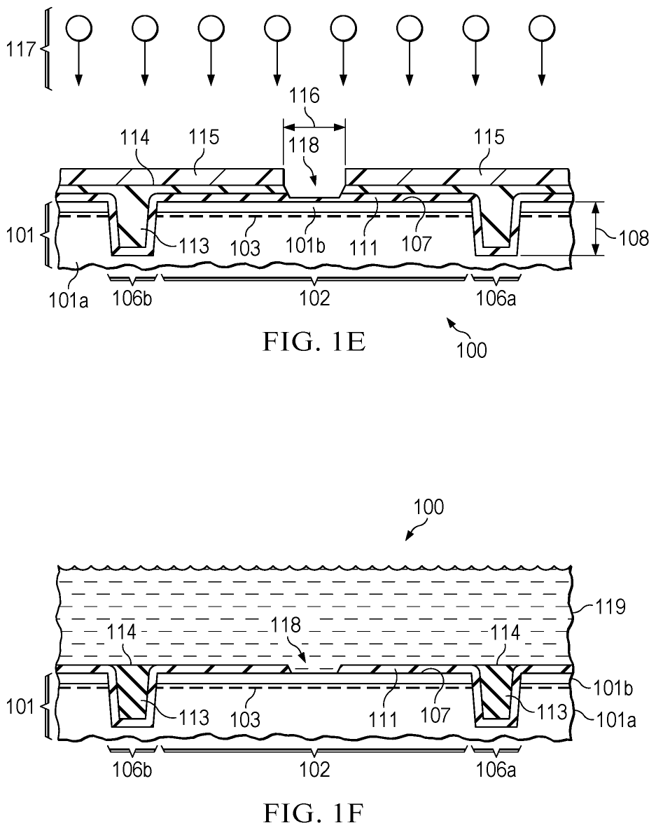

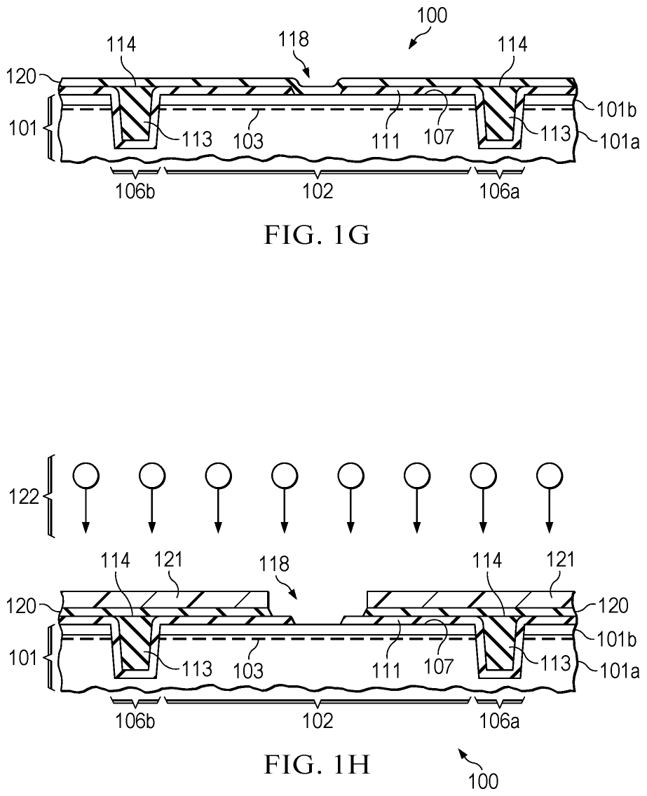

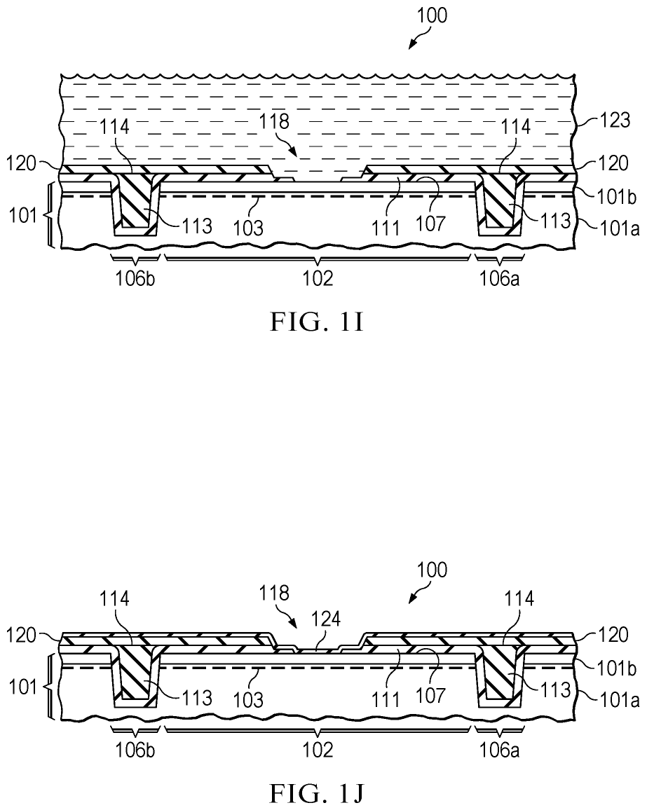

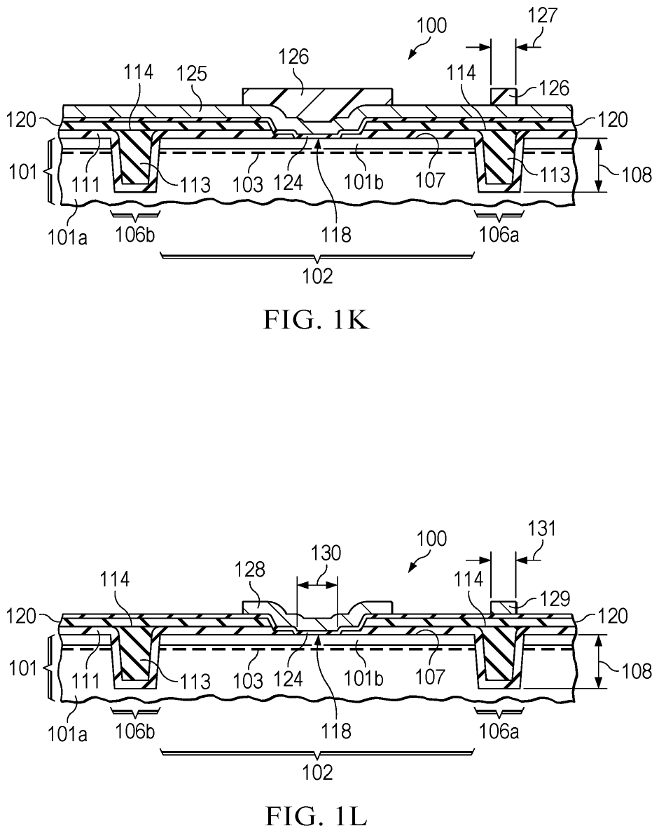

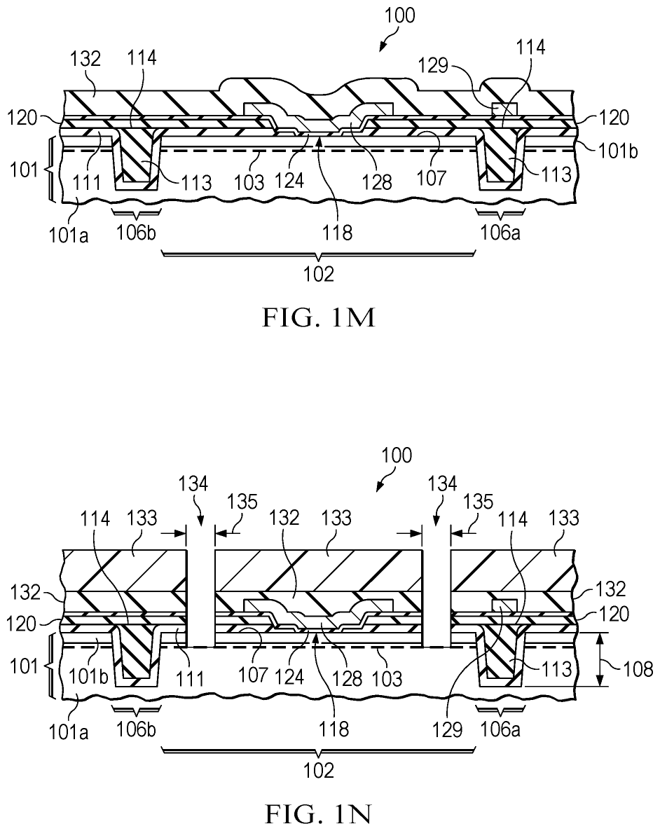

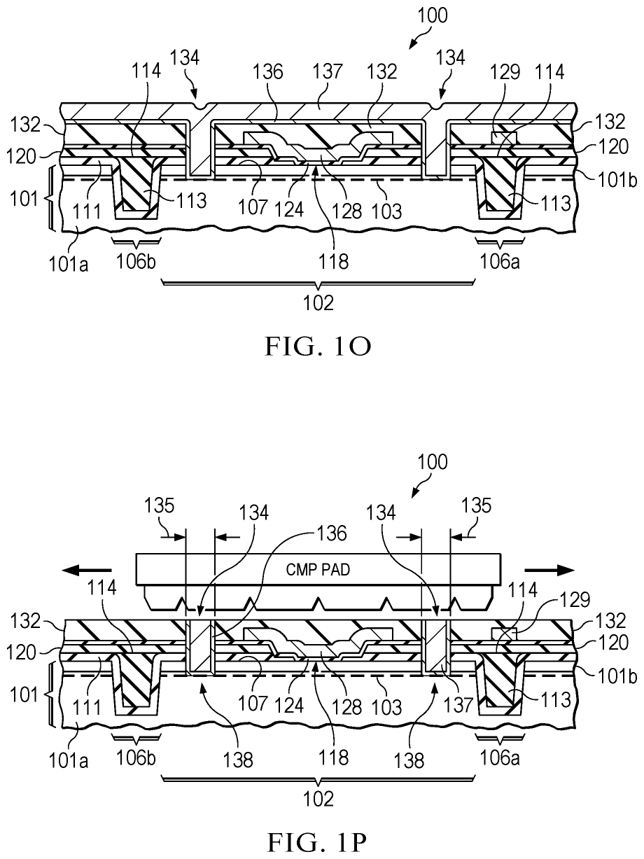

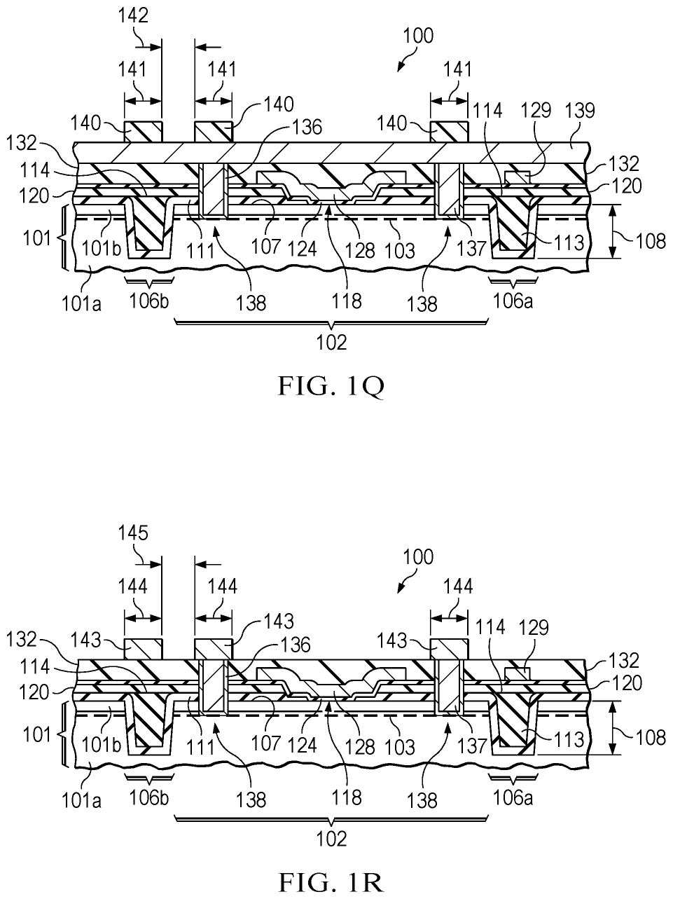

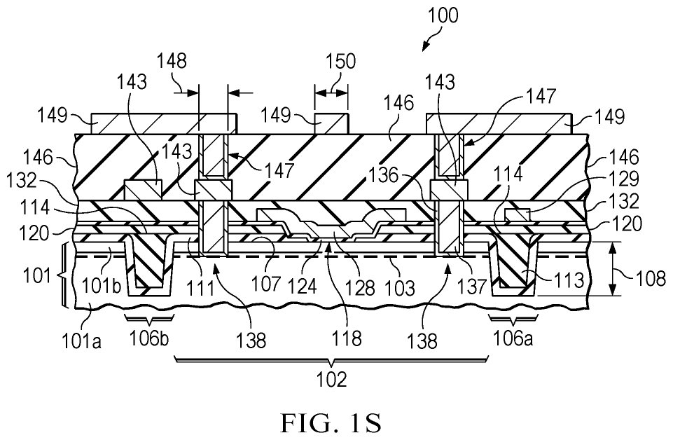

FIG. 1A through FIG. 1S are cross-sections of an example microelectronic device depicted in stages of a method of formation. Referring to FIG. 1A, the microelectronic device 100 includes a III-N semiconductor layer 101. A gallium nitride field effect transistor (GaN FET) 102 of the microelectronic device 100 is formed in and on the III-N semiconductor layer 101. In this example, the III-N semiconductor layer 101 includes a first III-N semiconductor sublayer 101a. The first III-N semiconductor sublayer 101a may be manifested as an undoped layer of gallium nitride, by way of example. The III-N semiconductor layer 101 of this example includes a second III-N semiconductor sublayer 101b on the first III-N semiconductor sublayer 101a. The second III-N semiconductor sublayer 101b may be manifested as a barrier layer of aluminum nitride and/or aluminum gallium nitride, having a band gap energy higher than a band gap energy of the first III-N semiconductor sublayer 101a. The second III-N semiconductor sublayer 101b produces a two-dimensional electron gas (2DEG) 103 in the first III-N semiconductor sublayer 101a, immediately under the second III-N semiconductor sublayer 101b. The first III-N semiconductor sublayer 101a and the second III-N semiconductor sublayer 101b may be formed by epitaxial processes.

An etch mask 104 is formed over the III-N semiconductor layer 101, covering an area for the GaN FET 102, and exposing the III-N semiconductor layer 101 in areas for topological structures. The etch mask 104 includes hard mask material such as silicon dioxide or titanium.

A reactive ion etch (RIE) process 105 removes a portion of the III-N semiconductor layer 101 where exposed by the etch mask 104 to form a first topological structure 106a and a second topological structure 106b in the III-N semiconductor layer 101, adjacent to the GaN FET 102. The RIE process 105 may use chlorine radicals and argon ions, labeled “CI” and “Ar⁺”, respectively, in FIG. 1A. The etch process may be performed in an inductively coupled plasma (ICP) tool, to provide control over a density of the chlorine radicals and an energy of the argon ions. The RIE process 105 may be implemented as a timed etch process.

The first topological structure 106a and the second topological structure 106b may be manifested in this example as a first opening 106a and a second opening 106b, extending to a top surface 107 of the III-N semiconductor layer 101. The top surface 107 extends into the first topological structure 106a and the second topological structure 106b, and so the top surface 107 is not planar over the complete III-N semiconductor layer 101. Portions of the top surface 107 may be planar, such as the top surface 107 adjacent to the first topological structure 106a and the second topological structure 106b. A maximum vertical dimension 108 of the first topological structure 106a and the second topological structure 106b may be 500 nanometers to 1 micron, by way of example. A maximum lateral dimension 109 of the first topological structure 106a and the second topological structure 106b at the top surface 107 may be less than the maximum vertical dimension 108. A sidewall angle 110 of sidewalls of the first topological structure 106a and the second topological structure 106b may be less than 10 degrees from vertical, with respect to the top surface 107 adjacent to the first topological structure 106a and the second topological structure 106b. The first topological structure 106a and the second topological structure 106b may have similar dimensions, as a result of being formed concurrently.

Referring to FIG. 1B, a liner 111 is formed on the top surface 107 of the III-N semiconductor layer 101. The liner 111 extends onto the first topological structure 106a and the second topological structure 106b, contacting the III-N semiconductor layer 101. In this example, the liner 111 may contact the III-N semiconductor layer 101 across the first topological structure 106a and the second topological structure 106b, as depicted in FIG. 1B. The liner 111 includes silicon nitride, and may be formed by a low pressure chemical vapor deposition (LPCVD) process using dichlorosilane and ammonia, at 730° C. to 770° C., by way of example. The liner 111 may include less than 10 atomic percent hydrogen, which may advantageously reduce trapped charge during operation of the microelectronic device 100. The liner 111 may have a thickness 112 of 100 nanometers to 250 nanometers, by way of example.

Referring to FIG. 1C, a fill material 113 is formed on the liner 111. The fill material 113 includes silicon nitride. The fill material 113 may be formed by a plasma enhanced chemical vapor deposition (PECVD) process using silane and ammonia. The fill material 113 is sufficiently thick so as to extend above the first topological structure 106a and the second topological structure 106b at all locations across the III-N semiconductor layer 101. In this example, the fill material 113 fills the openings of the first topological structure 106a and the second topological structure 106b. The PECVD process may advantageously provide a lower cost and faster cycle time for forming silicon nitride in the fill material 113 than an LPCVD process.

Referring to FIG. 1D, the fill material 113 is planarized. The fill material 113 may be planarized by a CMP process using a CMP pad, labeled “CMP PAD” in FIG. 1D. The CMP process to planarize the silicon nitride in the fill material 113 may be similar to a CMP process used to planarize silicon dioxide, with higher pressure and higher rotational speed. Other methods for planarizing the fill material 113 are within the scope of this example. After the fill material 113 is planarized, a top surface 114 of the fill material 113 is planar, that is, deviations in the top surface 114 are less than 10 percent of the maximum vertical dimension 108 of the topological structures 106a and 106b. The top surface 114 is parallel to the top surface 107 of the III-N semiconductor layer 101 adjacent to the first topological structure 106a and the second topological structure 106b.

Referring to FIG. 1E, a gate recess etch mask 115 is formed over the fill material 113, exposing the fill material 113 in an area for a combined gate/field plate 128 of the GaN FET 102, shown in FIG. 1L. The gate recess etch mask 115 includes photoresist and/or hard mask material. In this example, the gate recess etch mask 115 covers the first topological structure 106a and the second topological structure 106b. A width 116 of an opening in the gate recess etch mask 115 over the area for the combined gate/field plate 128 may be less than the maximum vertical dimension 108 of the topological structures 106a and 106b, which may be advantageously facilitated by the planarity of the top surface 114 of the fill material 113. Printing features such as lines and spaces in photoresist layers over surfaces with topological structures is problematic when the lateral dimensions of the lines and spaces approaches vertical dimensions of the topological structures. Having the width 116 of the opening in the gate recess etch mask 115 over the area for the combined gate/field plate 128 to be less than the maximum vertical dimension 108 of the topological structures 106a and 106b may advantageously provide an improved on-state current and switching speed of the microelectronic device 100.

A gate recess etch process 117 removes the fill material 113 and a portion of the liner 111 where exposed by the gate recess etch mask 115, to form a gate recess 118 in the fill material 113 and the liner 111. The gate recess etch process 117 may include an RIE process using fluorine radicals and hydrogen ions, by way of example. The gate recess etch process 117 of this example leaves a portion of the liner 111 on the III-N semiconductor layer 101 where exposed by the gate recess etch mask 115. The gate recess etch process 117 may be implemented as a timed etch process.

After the gate recess etch process 117 is completed, the gate recess etch mask 115 is removed. Photoresist in the gate recess etch mask 115 may be removed using an oxygen-containing plasma process, such as an asher process, followed by a wet clean process using an aqueous mixture of hydrogen peroxide and ammonium hydroxide. Hard mask material in the gate recess etch mask 115 may be removed by a wet etch process using a dilute aqueous buffered solution of hydrofluoric acid.

Referring to FIG. 1F, a gate recess wet etch process 119 removes at least a portion of the liner 111 under the gate recess 118. The gate recess wet etch process 119 may expose the III-N semiconductor layer 101 in the gate recess 118. The gate recess wet etch process 119 may include a wet etch process using an aqueous activated solution of phosphoric acid at 140° C., by way of example. Other formulations for the gate recess wet etch process 119 are within the scope of this example. The gate recess wet etch process 119 may remove a portion, or all, of the fill material 113 above the III-N semiconductor layer 101 outside of the first topological structure 106a and the second topological structure 106b, as indicated in FIG. 1F. After the gate recess wet etch process 119 is completed, the top surface 114 of the fill material 113 remains planar and parallel to the top surface 107 of the III-N semiconductor layer 101 adjacent to the first topological structure 106a and the second topological structure 106b. In one version of this example, the top surface 114 of the fill material 113 may be above the top surface 107 of the III-N semiconductor layer 101 adjacent to the topological structures 106a and 106b. In another version, the top surface 114 of the fill material 113 may be coplanar with the top surface 107 of the III-N semiconductor layer 101 adjacent to the topological structures 106a and 106b. In a further version, the top surface 114 of the fill material 113 may be below the top surface 107 of the III-N semiconductor layer 101 adjacent to the topological structures 106a and 106b. In some versions of this example, remaining portions of the fill material 113 may be located laterally within the topological structures 106a and 106b.

Referring to FIG. 1G, a gate field relief layer 120 is formed over an existing top surface of the microelectronic device 100, extending into the gate recess 118. The gate field relief layer 120 may include silicon nitride, and may be 100 nanometers to 250 nanometers thick, by way of example. The gate field relief layer 120 may be formed by an LPCVD process or a PECVD process.

Referring to FIG. 1H, a gate field relief mask 121 is formed over the gate field relief layer 120, exposing the gate field relief layer 120 over the gate recess 118 and an area around the gate recess 118. The gate field relief mask 121 may have a composition similar to the gate recess etch mask 115 of FIG. 1E.

A gate field relief etch process 122 removes at least a portion of the gate field relief layer 120 where exposed by the gate field relief mask 121. The gate field relief etch process 122 may expose the III-N semiconductor layer 101 in the gate recess 118. The gate field relief etch process 122 may be implemented as an RIE process similar to the gate recess etch process 117 of FIG. 1E.

After the gate field relief etch process 122 is completed, the gate field relief mask 121 is removed. The gate field relief mask 121 may be removed by processes similar to the processes used to remove the gate recess etch mask 115.

Referring to FIG. 1I, a gate recess clear etch process 123 removes any remaining material of the liner 111 and the gate field relief layer 120 from the III-N semiconductor layer 101 in the gate recess 118. The gate recess clear etch process 123 also removes a portion of the liner 111 adjacent to the gate recess 118. The gate recess clear etch process 123 may be implemented using a wet etch process similar to the gate recess wet etch process 119 of FIG. 1F.

Referring to FIG. 1J, a gate dielectric layer 124 is formed over the III-N semiconductor layer 101 in the gate recess 118, and extending over the liner 111 and the gate field relief layer 120. The gate dielectric layer 124 includes silicon nitride and may be formed by an LPCVD process to limit hydrogen in the gate dielectric layer 124. The gate dielectric layer 124 may be 50 nanometers to 100 nanometers thick, by way of example.

Referring to FIG. 1K, a gate layer 125 is formed over the gate dielectric layer 124. The gate layer 125 may include metal, such as titanium tungsten, and may be formed by a sputter process. The gate layer 125 may be 100 nanometers to 300 nanometers thick, by way of example.

A gate mask 126 is formed over the gate layer 125, covering the gate layer 125 over an area for the combined gate/field plate 128 and a field plate connected to the combined gate/field plate 128, shown in FIG. 1L. The gate mask 126 also covers the gate layer 125 over an area for an interconnect 129, shown in FIG. 1L, over the second topological structure 106b. The gate mask 126 may include photoresist, formed by a photolithographic process, or may be formed of hard mask material using a photoresist pattern, formed by a photolithographic process. The gate mask 126 over the area for the interconnect 129 may have a linewidth 127 that is less than the maximum vertical dimension 108 of the topological structures 106a and 106b, which may advantageously enable higher density interconnects and/or reduced die size for the microelectronic device 100. The linewidth 127 being less than the maximum vertical dimension 108 is enabled by the planarity of the top surface 114 of the fill material 113, which provides more uniform thickness for the photoresist used to form the gate mask 126.

The gate layer 125 is subsequently removed where exposed by the gate mask 126, by a gate etch process, not specifically shown, leaving the gate layer 125 covered by the gate mask 126, to form the combined gate/field plate 128 and the interconnect 129. The gate mask 126 is removed after the combined gate/field plate 128 and the interconnect 129 are formed.

Referring to FIG. 1L, the combined gate/field plate 128 has a gate length 130 that is less than the maximum vertical dimension 108 of the topological structures 106a and 106b, which is enabled by the width 116 of the opening in the gate recess etch mask 115 of FIG. 1E. The interconnect 129 has a linewidth 131 that is less than the maximum vertical dimension 108, which is enabled by the linewidth 127 of the gate mask 126.

Referring to FIG. 1M, a pre-metal dielectric (PMD) layer 132 is formed over an instant top surface of the microelectronic device 100. The PMD layer 132 may include silicon nitride, and may be 200 nanometers to 500 nanometers thick, by way of example. The PMD layer 132 may be formed by a PECVD process.

Referring to FIG. 1N, the PMD layer 132 is planarized, for example by a CMP process. Planarization of the PMD layer 132 is enabled by the fill material 113 and the planarity of the top surface 114 of the fill material 113; without the fill material 113, topology of the instant top surface of the microelectronic device 100 would require an excessive thickness of the PMD layer 132 to attain desired planarity and accurate thickness.

A contact etch mask 133 is formed over the planarized PMD layer 132, exposing the PMD layer 132 in areas for a contacts 138, shown in FIG. 1P, to a source and a drain of the GaN FET 102. A contact etch process, not specifically shown, removes the PMD layer 132 and underlying dielectric and III-N semiconductor material, where exposed by the contact etch mask 133, to form contact holes 134 that extend down to the 2DEG 103 in areas for the source and the drain. Lateral dimensions 135 of the contact holes 134 may be less than the maximum vertical dimension 108 of the topological structures 106a and 106b, which is enabled by the planarity of the PMD layer 132. Having the lateral dimensions 135 of the contact holes 134 to be less than the maximum vertical dimension 108 may advantageously enable reduced area and thus lower cost for the microelectronic device 100. After the contact holes 134 are formed, the contact etch mask 133 is removed.

Referring to FIG. 1O, a contact liner layer 136 is formed over the PMD layer 132, extending into the contact holes 134, contacting the PMD layer 132 and making electrical connections to the 2DEG 103. The contact liner layer 136 is electrically conductive. The contact liner layer 136 may include an adhesion sublayer, not specifically shown, of titanium, formed by a sputter process, and a barrier sublayer, not specifically shown, of titanium nitride, on the adhesion sublayer, formed by a reactive sputter process or an atomic layer deposition (ALD) process.

A contact fill layer 137 is formed on the contact liner layer 136, filling the contact holes 134. The contact fill layer 137 is electrically conductive. The contact fill layer 137 may include tungsten, and may be formed by a metal organic chemical vapor deposition (MOCVD) process using tungsten hexafluoride.

Referring to FIG. 1P, the contact fill layer 137 and the contact liner layer 136 are removed from over the PMD layer 132 outside of the contact holes 134, to form contacts 138 having damascene structures to the 2DEG 103 in the source and drain areas. The contact fill layer 137 and the contact liner layer 136 may be removed from over the PMD layer 132 by a tungsten CMP process, as indicated in FIG. 1P. The tungsten CMP process is enabled by the planarity of the PMD layer 132. The contacts 138 may have lateral dimensions equal to the lateral dimensions 135 of the contact holes 134. Other sublayer compositions, such as a cobalt fill layer, for the contacts 138 are within the scope of this example.

Referring to FIG. 1Q, an interconnect metal layer 139 is formed over the PMD layer 132, making electrical connections to the contacts 138. The interconnect metal layer 139 may include an adhesion sublayer of titanium or titanium tungsten on the PMD layer 132, a lower barrier sublayer of titanium nitride on the adhesion sublayer, a main sublayer of primarily aluminum on the lower barrier sublayer, and an upper barrier sublayer of titanium nitride on the main sublayer. The sublayers of the interconnect metal layer 139 are not specifically shown. Other compositions and sublayer configurations for the interconnect metal layer 139 are within the scope of this example.

An interconnect etch mask 140 is formed over the interconnect metal layer 139, covering the interconnect metal layer 139 in areas for first interconnects 143, shown in FIG. 1R. The interconnect etch mask 140 includes photoresist formed by a photolithographic process. The interconnect etch mask 140 may include anti-reflection material, such as a bottom anti-reflection coat (BARC). Linewidths 141 of the interconnect etch mask 140 may be less than the maximum vertical dimension 108 of the topological structures 106a and 106b, which is enabled by the planar surface of the PMD layer 132. Similarly, lateral spaces 142 of the interconnect etch mask 140 may be less than the maximum vertical dimension 108 of the topological structures 106a and 106b, which is enabled by the of the PMD layer 132.

The interconnect metal layer 139 is removed where exposed by the interconnect etch mask 140, leaving the interconnect metal layer 139 covered by the interconnect etch mask 140 to provide the first interconnects 143. The interconnect metal layer 139 may be removed by a series of RIE processes using fluorine radicals to etch the titanium nitride and titanium, and chlorine radicals to etch the aluminum. The interconnect etch mask 140 is subsequently removed.

Referring to FIG. 1R, the first interconnects 143 make electrical connections to the contacts 138. Lateral dimensions 144 of one or more of the first interconnects 143 may be less than the maximum vertical dimension 108 of the topological structures 106a and 106b. Similarly, lateral spaces 145 between two or more of the first interconnects 143 may be less than the maximum vertical dimension 108 of the topological structures 106a and 106b, enabled by the linewidths 141 and lateral spaces 142 of the interconnect etch mask 140. Having the lateral dimensions 144 and lateral spaces 145 of the interconnects less than the maximum vertical dimension 108 may advantageously enable reduced area and thus lower cost for the microelectronic device 100.

Referring to FIG. 1S, an inter-level dielectric (ILD) layer 146 is formed over the first interconnects 143 and the PMD layer 132. The ILD layer 146 may include primarily silicon nitride, and may be formed by a PECVD process. Alternatively, the ILD layer 146 may include primarily silicon dioxide, and may be formed by a PECVD process using tetraethoxysilane (TEOS), formally named tetraethyl orthosilicate.

The ILD layer 146 may be planarized, for example by a CMP process. Planarization of the ILD layer 146 is advantageously facilitated by the planarity of the top surface 114 of the fill material 113; as explained in reference to planarization of the PMD layer 132.

Vias 147 are formed through the ILD layer 146 to the first interconnects 143. The vias 147 may have damascene structures and compositions similar to the contacts 138, and may be formed by a similar process. Lateral dimensions 148 of the vias 147 may be less than the maximum vertical dimension 108 of the topological structures 106a and 106b, enabled by planarization of the ILD layer 146, and accruing the advantages of reduced area and fabrication cost.

Second interconnects 149 are formed over the ILD layer 146, making electrical connections to the vias 147. The second interconnects 149 may have structures and compositions similar to the first interconnects 143, and may be formed by a similar process. Linewidths 150 of one or more of the second interconnects 149 may be less than the maximum vertical dimension 108 of the topological structures 106a and 106b, enabled by planarization of the ILD layer 146, and accruing the advantages of reduced are and fabrication cost.

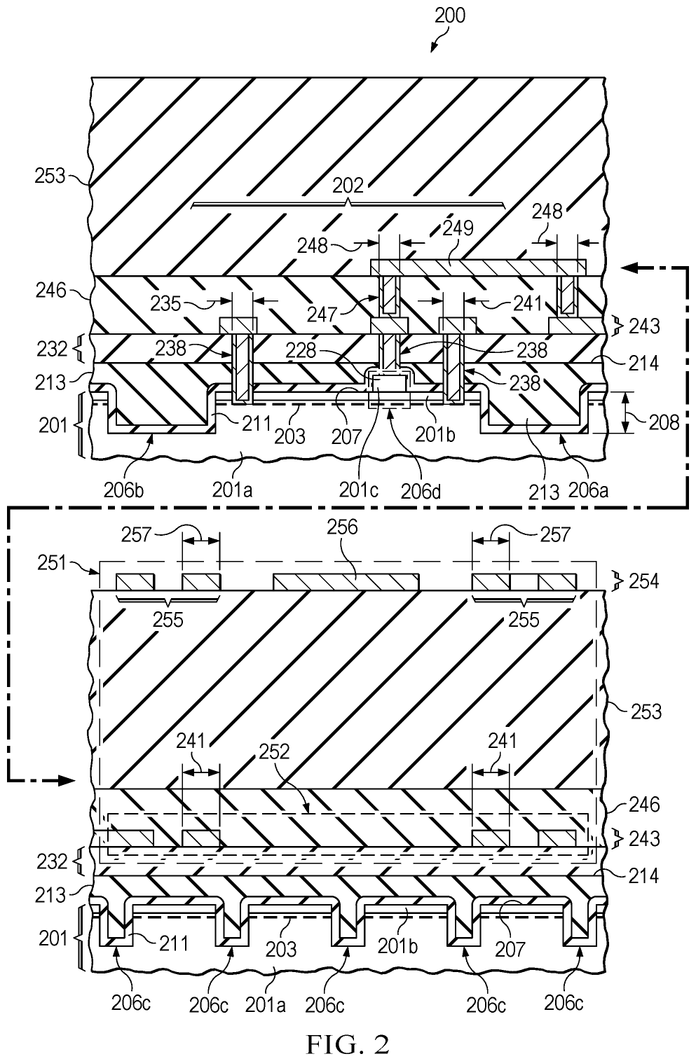

FIG. 2 is a cross section of another example microelectronic device having topological structures. Referring to FIG. 2, the microelectronic device 200 includes a III-N semiconductor layer 201. A GaN FET 202 is formed in and on the III-N semiconductor layer 201. A galvanic isolation component 251, connected to the GaN FET 202, is formed over the III-N semiconductor layer 201. The galvanic isolation component 251 may be manifested as an isolation transformer, as depicted in FIG. 2. Other manifestations of the galvanic isolation component 251, such as an isolation capacitor, are within the scope of this example.

In this example, the III-N semiconductor layer 201 includes a first III-N semiconductor sublayer 201a, which may be manifested as an undoped layer of gallium nitride. The III-N semiconductor layer 201 of this example includes a second III-N semiconductor sublayer 201b, which may be manifested as a barrier layer of aluminum nitride or aluminum gallium nitride, on the first III-N semiconductor sublayer 201a. The III-N semiconductor layer 201 of this example further includes a third III-N semiconductor sublayer 201c, which may be manifested as a layer of p-type gallium nitride, on the second III-N semiconductor sublayer 201b. The first III-N semiconductor sublayer 201a, the second III-N semiconductor sublayer 201b, and the third III-N semiconductor sublayer 201c may be formed by sequential epitaxial processes. The second III-N semiconductor sublayer 201b produces a 2DEG 203 in the first III-N semiconductor sublayer 201a, immediately under the second III-N semiconductor sublayer 201b.

A first topological structure 206a and a second topological structure 206b are formed in the III-N semiconductor layer 201, adjacent to the GaN FET 202. The first topological structure 206a and the second topological structure 206b may be manifested in this example as a first opening 206a and a second opening 206b, extending to a top surface 207 of the III-N semiconductor layer 201.

A plurality of third topological structures 206c is formed in the III-N semiconductor layer 201, under the galvanic isolation component 251. The third topological structures 206c may be manifested as third openings 206c in the III-N semiconductor layer 201, extending to the top surface 207.

A fourth topological structure 206d is formed in the III-N semiconductor layer 201, in which a portion of the third III-N semiconductor sublayer 201c is removed from the GaN FET 202, leaving a remaining portion of the third III-N semiconductor sublayer 201c to provide a gate 228 of the GaN FET 202. The fourth topological structure 206d may thus be manifested as a protrusion of the III-N semiconductor layer 201. The p-type gallium nitride of the third III-N semiconductor sublayer 201c in the gate 228 may shift the conduction band of the second III-N semiconductor sublayer 201b above the Fermi level, so that the 2DEG 203 is interrupted under the gate 228 when the GaN FET 202 is not in operation. Thus, the Gan FET 202 of this example may be an enhancement mode FET, also known as a normally off FET.

The top surface 207 of the III-N semiconductor layer 201 extends into the first, second, and third topological structures 206a, 206b, and 206c, and over the fourth topological structure 206d, and so the top surface 207 is not planar over the complete III-N semiconductor layer 201. Portions of the top surface 207 of this example are planar, such as the top surface 207 adjacent to the topological structures 206a, 206b, 206c and 206d.

A liner 211 is formed on the top surface 207 of the III-N semiconductor layer 201, extending onto the topological structure 206a, 206b, and 206c which are manifested as openings in the III-N semiconductor layer 201, and over the fourth topological structure 206d, contacting the III-N semiconductor layer 201. The liner 211 includes silicon nitride.

A fill material 213 is formed on the liner 211 and planarized, filling the topological structures 206a, 206b, and 206c which are manifested as openings in the III-N semiconductor layer 201. The fill material 213 may optionally cover the fourth topological structure 206d which is manifested as a protrusion of the III-N semiconductor layer 201. The fill material 213 may include silicon nitride. Other materials, such as silicon dioxide or silicon oxynitride, are within the scope of this example. A top surface 214 of the fill material 213 is planar, that is, deviations in the top surface 214 are less than 10 percent of the maximum vertical dimension 208 of the topological structures 206a through 206d. The top surface 214 is parallel to the top surface 207 of the III-N semiconductor layer 201 adjacent to the topological structures 206a through 206d.

A PMD layer 232 is formed over the fill material 213. The PMD layer 232 may include silicon nitride. A top surface of the PMD layer 232 may be planar, as a result of the planarity of the top surface 214 of the fill material 213. Contacts 238 are formed through the PMD layer 232, the fill material 213, and the liner 211, extending to the 2DEG 203 in source and drain regions of the GaN FET 202, and to the gate 228. The contacts 238 may have damascene structures and compositions similar to the contacts 138 of FIG. 1P, enabled by the planarity of the top surface 214. The contacts 238 may have lateral dimensions 235 less than a maximum vertical dimension 208 of the topological structures 206a through 206d, enabled by the planarity of the top surface 214.

First interconnects 243 are formed over the PMD layer 232, making electrical connections to the contacts 238. The first interconnects 243 may have structures and compositions similar to the first interconnects 143 of FIG. 1R. Some of the first interconnects 243 provide electric connections to the source, drain, and gate 228 of the GaN FET 202. Some of the first interconnects 243 provide a lower winding 252 of the galvanic isolation component 251. Some of the first interconnects 243 may have lateral dimensions 241 less than the maximum vertical dimension 208 of the topological structures 206a through 206d, enabled by the planarity of the top surface 214, advantageously enabling reduced area and fabrication cost.

An ILD layer 246 is formed over the PMD layer 232 and the first interconnects 243. The ILD layer 246 may include silicon nitride, silicon dioxide, or a combination thereof, by way of example. The ILD layer 246 may be planarized, which may be advantageously facilitated by the planarity of the top surface 214 of the fill material 213.

Vias 247 are formed through the ILD layer 246 to the first interconnects 243. The vias 247 may have damascene structures and compositions similar to the contacts 238. Lateral dimensions 248 of the vias 247 may be less than the maximum vertical dimension 208 of the topological structures 206a through 206d, enabled by planarization of the ILD layer 246, and accruing the advantages of reduced area and fabrication cost.

Second interconnects 249 are formed over the ILD layer 246, making electrical connections to the vias 247. The second interconnects 249 may have structures and compositions similar to the first interconnects 243. One or more of the second interconnects 249 may provide a connection between the lower winding 252 of the galvanic isolation component 251 and the gate 228 of the GaN FET 202, as shown in FIG. 2.

A galvanic isolation dielectric layer 253 is formed over the ILD layer 246 and the second interconnects 249. The galvanic isolation dielectric layer 253 may include one or more sublayers of silicon nitride and/or silicon dioxide. Upper interconnects 254 are formed over the galvanic isolation dielectric layer 253. The upper interconnects 254 may include an aluminum layer suitable for wire bonding. The upper interconnects 254 include an upper winding 255 of the galvanic isolation component 251 and an upper winding bond pad 256 connected to the upper winding 255. The galvanic isolation dielectric layer 253 is sufficiently thick to provide reliable operation of the galvanic isolation component 251 when an operational potential difference is applied between the upper winding 255 and the lower winding 252. The upper winding 255 may have linewidths 257 less than the maximum vertical dimension 208 of the topological structures 206a through 206d, enabled by planarization of the ILD layer 246, and accruing the advantages of reduced area and fabrication cost. The galvanic isolation component 251 may advantageously enable heterogeneous integration of the GaN FET 202 with a signal processing component at lower cost compared to using a separate isolation component on a separate substrate.

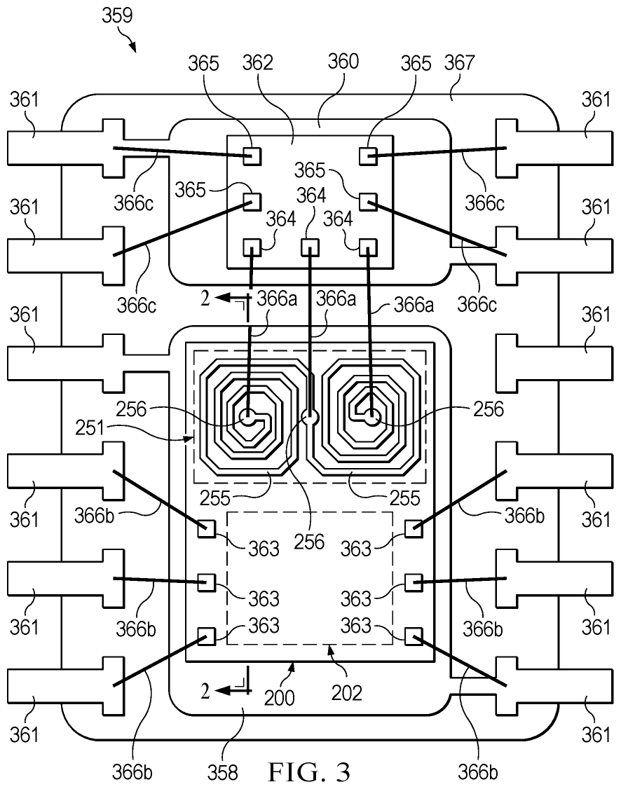

FIG. 3 is a top view of a multi-chip module including the microelectronic device 200 of FIG. 2 and a separate signal processing device. The multi-chip module 359 may be manifested as a small outline integrated circuit (SOIC), by way of example. The multi-chip module 359 of this example includes a first die pad 358 and a second die pad 360, and external leads 361. The first die pad 358 may be connected to one or more of the external leads 361 by conductive segments, as depicted in FIG. 3. Similarly, the second die pad 360 may be connected to other instances of the external leads 361.

The microelectronic device 200 is attached to the first die pad 358. The microelectronic device 200 may be attached to the first die pad 358 by solder, electrically conductive adhesive, or an insulating layer. The signal processing device 362 is attached to the second die pad 360, by solder, electrically conductive adhesive, or an insulating layer.

The microelectronic device 200 has the upper winding 255 and upper winding bond pads 256 of the galvanic isolation component 251, along with first additional bond pads 363. One or more of the additional bond pads 363 may be connected to the source and drain of the GaN FET 202, to provide power and ground. The signal processing device 362 has signal bond pads 364 and second additional bond pads 365.

The upper winding bond pads 256 are connected to the signal bond pads 364 by first wire bonds 366a. The first additional bond pads 363 of the microelectronic device 200 are connected to one or more of the external leads 361 by second wire bonds 366b. The second additional bond pads 365 of the signal processing device 362 are connected to one or more of the external leads 361 by third wire bonds 366c. The first wire bonds 366a, the second wire bonds 366b, and the third wire bonds 366c may be formed sequentially by a single wire bonding process.

The multi-chip module 359 includes an encapsulation material 367 covering the microelectronic device 200 and the signal processing device 362, and surrounding the wire bonds 366a, 366b, and 366c. The encapsulation material 367 may include epoxy, with optional filler particles to reduce thermal expansion and increase dielectric strength. The encapsulation material 367 may be formed by an injection molding process.

Having the galvanic isolation component 251 integrated into the microelectronic device 200 may enable heterogeneous integration of the GaN FET 202 with the signal processing device 362 without need for a separate galvanic isolation chip, advantageously reducing cost and size of the multi-chip module 359.

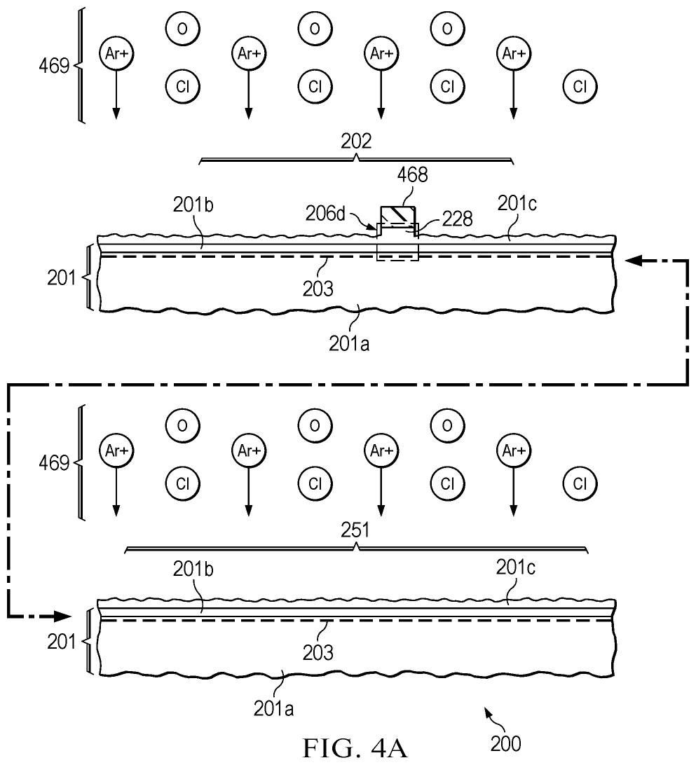

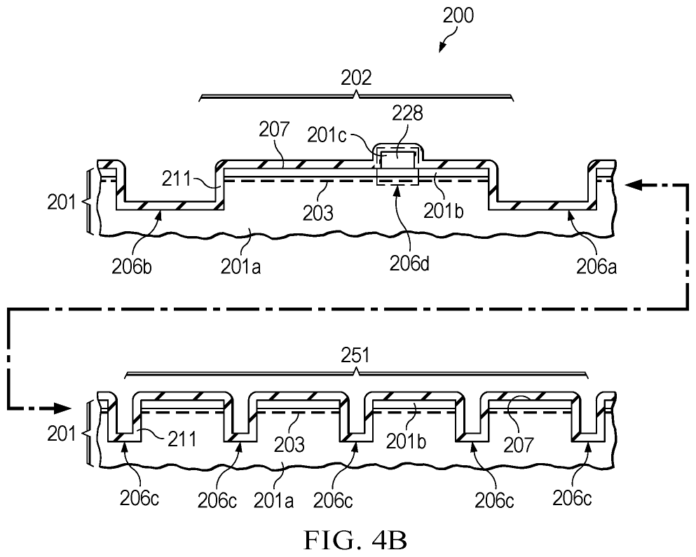

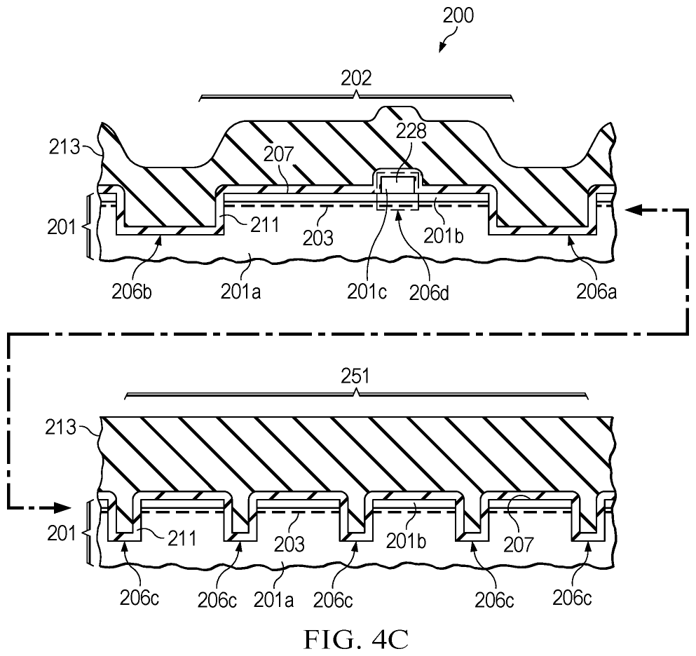

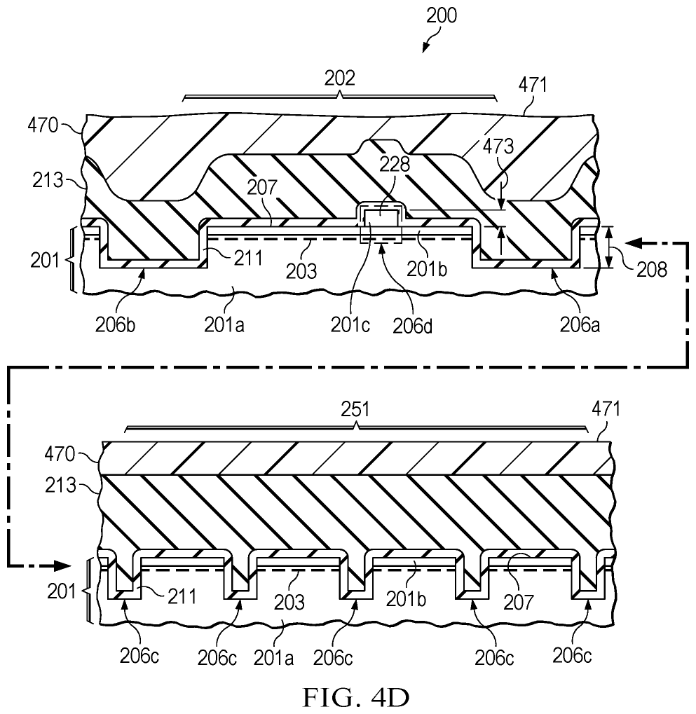

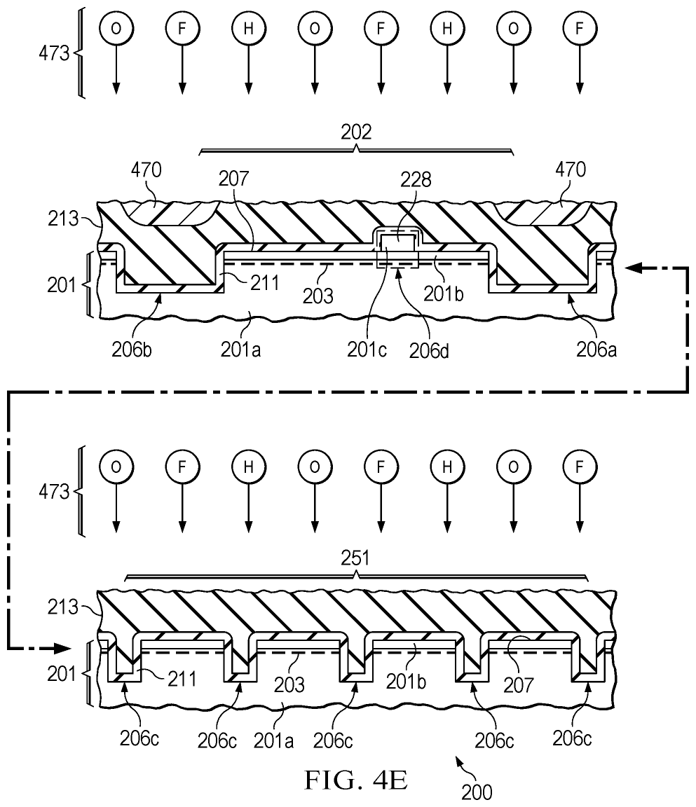

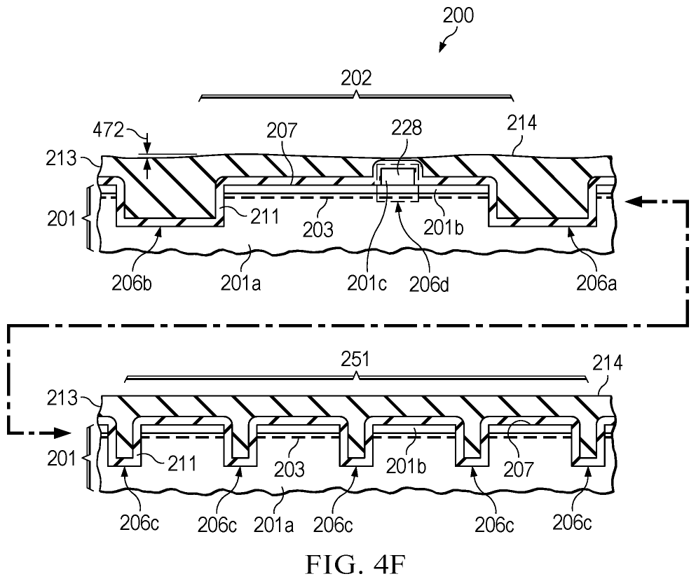

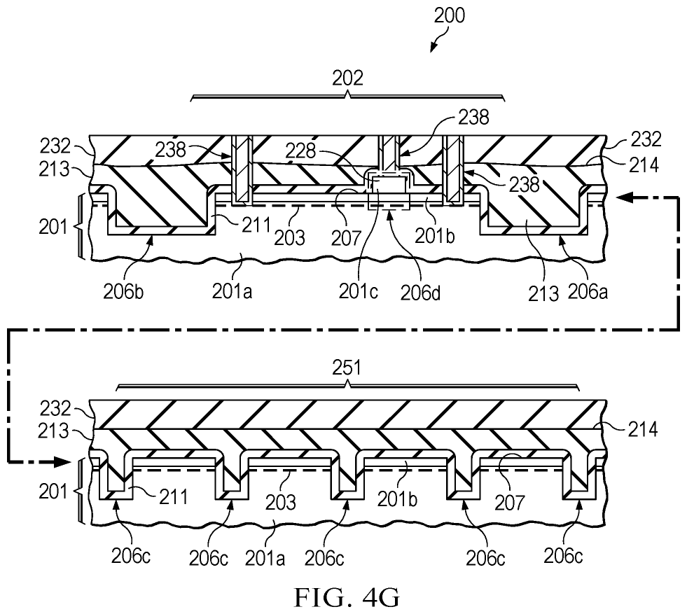

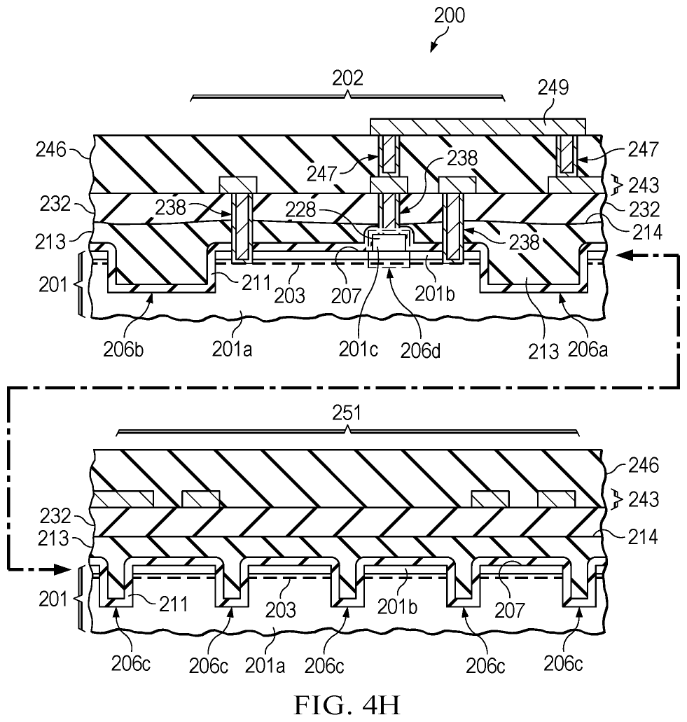

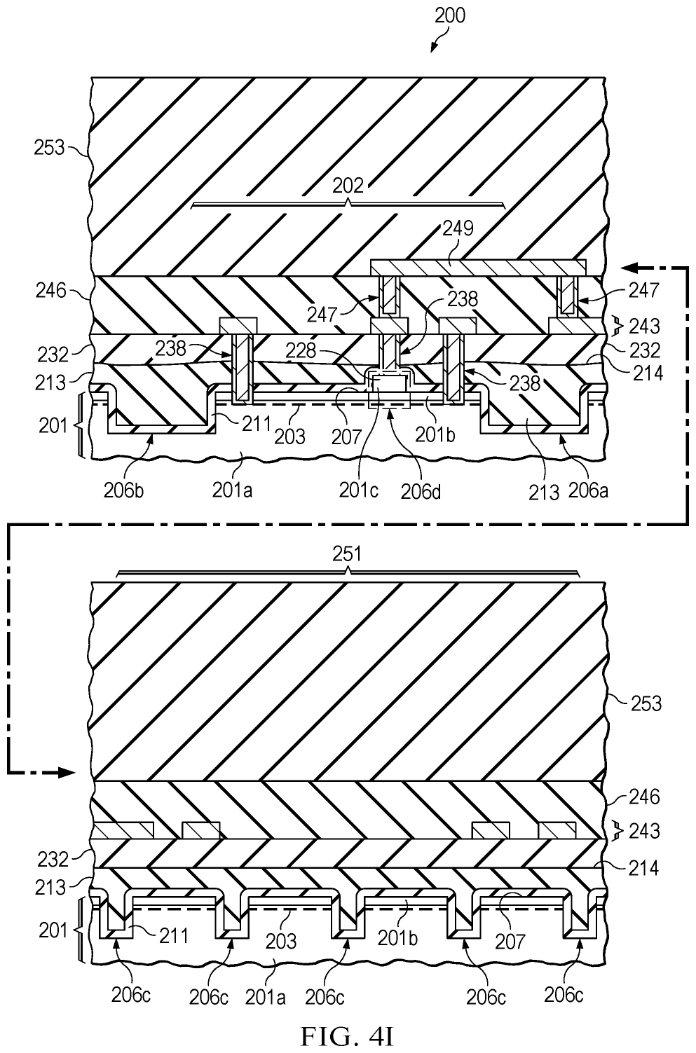

FIG. 4A through FIG. 4J are cross sections of the microelectronic device 200 of FIG. 2, depicted in stages of an example method of formation. Referring to FIG. 4A, the first III-N semiconductor sublayer 201a may be formed on a silicon substrate, not specifically shown. The first III-N semiconductor sublayer 201a, the second III-N semiconductor sublayer 201b, and the third III-N semiconductor sublayer 201c are formed by sequential epitaxial processes.

A gate etch mask 468 is formed over the third III-N semiconductor sublayer 201c, covering an area for the gate 228. The gate etch mask 468 may expose the third III-N semiconductor sublayer 201c in an area for the galvanic isolation component 251, as depicted in FIG. 4A. The gate etch mask 468 may include photoresist formed by a photolithographic process, and may include hard mask material such as silicon dioxide.

An RIE process 469 removes the third III-N semiconductor sublayer 201c where exposed by the gate etch mask 468, leaving the third III-N semiconductor sublayer 201c under the gate etch mask 468 to form the gate 228. The gate 228 is the fourth topological structure 206d. The RIE process 469 may be performed in an ICP etcher. The RIE process 469 includes a chemical etchant species, a physical etchant species, and an aluminum passivating species, to provide selectivity to the second III-N semiconductor sublayer 201b which includes aluminum. The chemical etchant species may be implemented as chlorine radicals, labeled “CI” in FIG. 4A, or bromine radicals, for example. The physical etchant species may be implemented by one or more ion species. Examples of the physical etchant species include argon ions, labeled Ar⁺ in FIG. 4A, fluorine ions, helium ions, or oxygen ions. Other ion species in the physical etchant species are within the scope if this example. The aluminum passivating species may be implemented as oxygen radicals, labeled “O” in FIG. 4A, or fluorine radicals.

FIG. 4A depicts the RIE process 469 partway to completion. After the third III-N semiconductor sublayer 201c is removed where exposed by the gate etch mask 468, the gate etch mask 468 is removed.

Referring to FIG. 4B, the first topological structure 206a and the second topological structure 206b are formed in the III-N semiconductor layer 201 adjacent to the GaN FET 202. The third topological structures 206c are formed in the III-N semiconductor layer 201 under an area for the galvanic isolation component 251. The first, second, and third topological structures 206a, 206b, and 206c may be formed concurrently by an RIE process, as disclosed in reference to FIG. 1A.

Subsequently, the liner 211 is formed on the top surface 207 of the III-N semiconductor layer 201, extending into the first, second, and third topological structures 206a, 206b, and 206c and over the fourth topological structure 206d. The liner 211 may be formed by an LPCVD process, to provide a hydrogen content less than 10 atomic percent.

Referring to FIG. 4C, the fill material 213 is formed on the liner 211. The fill material 213 may be formed by a conformal process, such as a PECVD process, so that the fill material 213 is not planar, due to the topological structures 206a through 206d. Other processes to form the fill material 213, such as a high density plasma (HDP) process, are within the scope of this example.

Referring to FIG. 4D, a polymer material 470 is formed over the fill material 213 by a spin coat process. The polymer material 470 may include photoresist with polyisoprene, photoresist with novolac resin, or novolac resin alone, by way of example. The spin coat process produces a top surface 471 of the polymer material 470 that is planar, that is, deviations in the top surface 471 of the polymer material 470 are less than 10 percent of the maximum vertical dimension 208 of the topological structures 206a through 206d. The polymer material 470 may be formed by more than one application using the spin coat process, followed by baking or curing to reduce solvents in the polymer material 470. The third topological structures 206c may provide a more consistent density of the III-N semiconductor layer 201 and openings, compared to a region having all III-N semiconductor layer 201 or a very wide opening, which may advantageously provide a more planar top surface 471 of the polymer material 470.

Referring to FIG. 4E, an etchback process 473 removes the polymer material 470 and the fill material 213 at comparable etch rates, to transfer the planarity of the original top surface 471 of the polymer material 470, as shown in FIG. 4D, into the fill material 213. The etchback process 473 may be a plasma etch process using fluorine, oxygen, and hydrogen, labeled “F”, “O”, and “H”, respectively, in FIG. 4E. Flow rates of gas reagents such as oxygen and CF₄, used in the etchback process 473 may be adjusted to balance etch rates of the polymer material 470 and the fill material 213. FIG. 4E depicts the etchback process 473 partway to completion.

FIG. 4F depicts the microelectronic device 200 after completion of the etchback process 473. The top surface 214 of the fill material 213 is planar, that is, deviations 472 in the top surface 214 are less than 10 percent of the maximum vertical dimension 208 of the topological structures 206a through 206d. The top surface 214 of the fill material 213 is parallel to the top surface 207 of the III-N semiconductor layer 201 adjacent to the topological structures 206a through 206d.

Referring to FIG. 4G, the PMD layer 232 is formed over the planarized fill material 213. The PMD layer 232 may be formed by one or more PECVD processes. The contacts 238 are formed through the PMD layer 232, the fill material 213, and the liner 211, making electrical connections to the 2DEG 203 in source and drain regions of the GaN FET 202, and to the gate 228. The contacts 238 may be formed by a tungsten damascene process as disclosed in reference to FIG. 1N through FIG. 1P.

Referring to FIG. 4H, the first interconnects 243 are formed over the PMD layer 232, making electrical connections to the contacts 238. The first interconnects 243 may be formed by an etched aluminum process as disclosed in reference to FIG. 1Q and FIG. 1R.

The ILD layer 246 is formed over the PMD layer 232 and the first interconnects 243. The ILD layer 246 may be formed by one or more PECVD processes. The ILD layer 246 may be planarized, for example by a CMP process, not specifically shown, similar to the CMP process of FIG. 1D, which may be advantageously facilitated by the planarity of the top surface 214 of the fill material 213.

The vias 247 are formed through the ILD layer 246 to the first interconnects 243. The vias 247 may have been formed by a tungsten damascene process similar to the process used to form contacts 238, enabled by planarization of the ILD layer 246.

The second interconnects 249 are formed over the ILD layer 246, making electrical connections to the vias 247. The second interconnects 249 may be formed by processes similar to the processes used to form the first interconnects 243.

Referring to FIG. 4I, the galvanic isolation dielectric layer 253 is formed over the ILD layer 246 and the second interconnects 249. The galvanic isolation dielectric layer 253 may be formed by one or more PECVD processes. The galvanic isolation dielectric layer 253 may have compressive stress, which may advantageously compensate for tensile stress in the III-N semiconductor layer 201, in versions of this example in which the III-N semiconductor layer 201 is formed on a silicon substrate, not specifically shown. The galvanic isolation dielectric layer 253 may be subsequently planarized, for example by a CMP process. Formation of the microelectronic device 200 continues with formation of the upper interconnects 254 of FIG. 2.

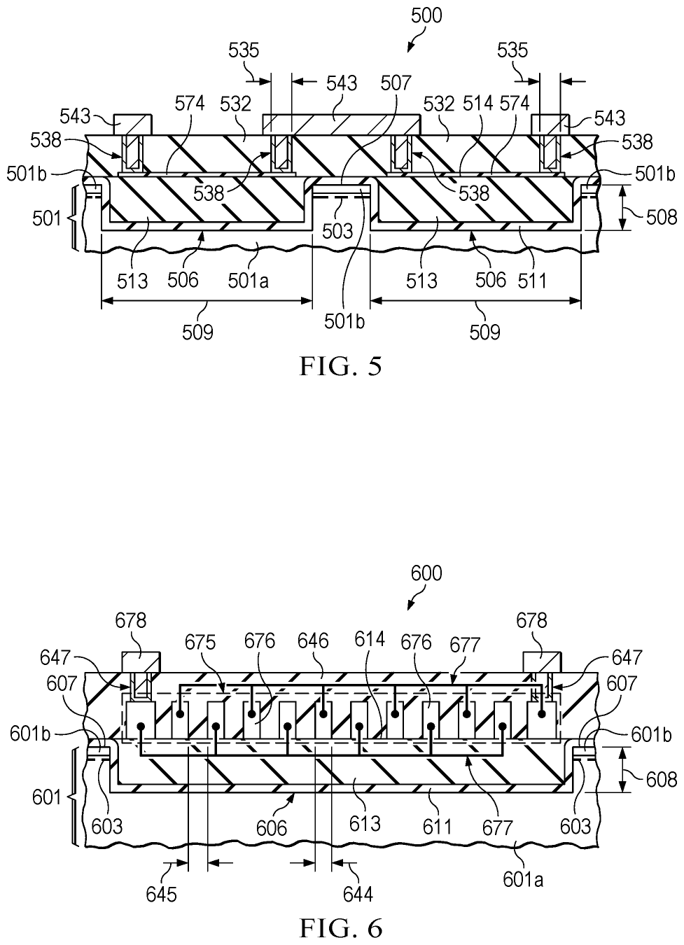

FIG. 5 is a cross section of an example microelectronic device that includes topological structures and passive components over the topological structures. The microelectronic device 500 includes a III-N semiconductor layer 501. The III-N semiconductor layer 501 may include a first III-N semiconductor sublayer 501a, such as an undoped layer of gallium nitride, and may further include a second III-N semiconductor sublayer 501b, such as a barrier layer, on the first III-N semiconductor sublayer 501a, as depicted in FIG. 5. The second III-N semiconductor sublayer 501b, if present, may produce a 2DEG 503 in the first III-N semiconductor sublayer 501a, immediately under the second III-N semiconductor sublayer 501b.

A plurality of topological structures 506 are formed in the III-N semiconductor layer 501. The topological structures 506 may be manifested as openings 506 in the III-N semiconductor layer 501, extending to a top surface 507 of the III-N semiconductor layer 501. In this example, a maximum lateral dimension 509 of each topological structure 506 may be greater than a maximum vertical dimension 508 of the topological structure 506. The topological structures 506 extend through the second III-N semiconductor sublayer 501b, so that the 2DEG 503 does not extend across the topological structures 506. A liner 511 including silicon nitride is formed on the top surface 507 of the III-N semiconductor layer 501, extending onto the topological structures 506, contacting the III-N semiconductor layer 501.

A fill material 513, which may include silicon nitride, is formed on the liner 511 and planarized, filling the topological structures 506. The fill material 513 may be planarized by a CMP process or an etchback process, by way of example. Other methods for planarizing the fill material 513 are within the scope of this example. A top surface 514 of the fill material 513 is planar, that is, deviations in the top surface 514 are less than 10 percent of the maximum vertical dimension 508 of the topological structures 506. The top surface 514 is parallel to the top surface 507 of the III-N semiconductor layer 501 adjacent to the topological structures 506.

One or more of the passive components 574, manifested in this example as thin film resistors 574, are formed over the fill material 513. The thin film resistors 574 may be located entirely over the topological structures 506, which may advantageously reduce capacitive coupling to the 2DEG 503. The thin film resistors 574 may include alloys of nickel, chromium, titanium, tantalum, molybdenum, silicon, and any metals of the platinum group (ruthenium, rhodium, palladium, osmium, iridium, and platinum). The thin film resistors 574 may include other elements, such as aluminum, copper, oxygen, nitrogen, or carbon, to impart desired properties to the thin film resistors 574. The thin film resistors 574 may be 5 nanometers to 50 nanometers thick, by way of example. A protective layer, not specifically shown, may be formed over the thin film resistors 574 to reduce degradation during subsequent fabrication processes. Planarity of the fill material 513 may advantageously provide improved accuracy and reliability for the thin film resistors 574 compared to thin film resistors on a non-planar surface.

A PMD layer 532, which may include silicon nitride, is formed over the fill material 513 and the thin film resistors 574. Contacts 538 are formed through the PMD layer 532 to provide electrical connections to the thin film resistors 574. A top surface of the PMD layer 532 may be sufficiently planar, as a result of the planarity of the top surface 514 of the fill material 513 and the relatively low thickness of the thin film resistors 574, to enable forming the contacts 538 by a tungsten damascene process. The contacts 538 may have lateral dimensions 535 less than a maximum vertical dimension 508 of the topological structures 506, enabled by the planarity of the top surface 514. First interconnects 543 are formed over the PMD layer 532, making electrical connections to the contacts 538. Formation of the microelectronic device 500 may be continued with forming addition layers of dielectric material and additional interconnect levels.

FIG. 6 is a cross section of an example microelectronic device that includes a topological structure and a passive component above the topological structure. The microelectronic device 600 includes a III-N semiconductor layer 601. The III-N semiconductor layer 601 may include a first III-N semiconductor sublayer 601a, such as an undoped layer of gallium nitride, and may further include a second III-N semiconductor sublayer 601b, such as a barrier layer, on the first III-N semiconductor sublayer 601a, as depicted in FIG. 6. The second III-N semiconductor sublayer 601b, if present, may produce a 2DEG 603 in the first III-N semiconductor sublayer 601a, immediately under the second III-N semiconductor sublayer 601b.

A topological structure 606 is formed in the III-N semiconductor layer 601. The topological structure 606 may be manifested as an opening 606 in the III-N semiconductor layer 601, extending from a top surface 607 of the III-N semiconductor layer 601 to a maximum vertical dimension 608 of the topological structure 606. The topological structure 606 extends through the second III-N semiconductor sublayer 601b, so that the 2DEG 603 does not extend across the topological structures 606. A liner 611 including silicon nitride is formed on the top surface 607 of the III-N semiconductor layer 601, extending onto the topological structure 606, contacting the III-N semiconductor layer 601.

A fill material 613, which may include silicon nitride, is formed on the liner 611 and planarized, filling the topological structure 606. A top surface 614 of the fill material 613 is planar, that is, deviations in the top surface 614 are less than 10 percent of the maximum vertical dimension 608 of the topological structure 606. The top surface 614 is parallel to the top surface 607 of the III-N semiconductor layer 601 adjacent to the topological structure 606.

The passive component 675, manifested in this example as a metal insulator metal (MIM) capacitor 675, includes metal plates 676 over the fill material 613, above the topological structure 606. Alternating instances of the metal plates 676 are electrically connected by bus conductors 677 to form the MIM capacitor 675. The metal plates 676 may be members of an interconnect level of the microelectronic device 600. The bus conductors 677 may be extensions of the metal plates 676, or may be members of another interconnect level, by way of example. Lateral dimensions 644 of the metal plates 676 may be less than the maximum vertical dimension 608 of the topological structure 606, enabled by the planarity of the fill material 613. Lateral spaces 645 of the metal plates 676 may similarly be less than the maximum vertical dimension 608 of the topological structure 606, enabled by the planarity of the fill material 613. Having the lateral dimensions 644 and the lateral spaces 645 less than the maximum vertical dimension 608 may advantageously provide a capacitance density for the MIM capacitor 675 that is higher than can be economically formed without the planar surface of the fill material 613. Having the MIM capacitor 675 above the topological structure 606 may advantageously reduce capacitive coupling to the 2DEG layer 603.

An ILD layer 646 may be formed over the fill material 613 and the metal plates 676. Vias 647 are formed through the ILD layer 646 to make electrical connections to one or more of the metal plates 676. Capacitor terminals 678 are formed over the ILD layer 646, making electrical connections to the metal plates 676 through the vias 647, and through the bus conductors 677. The capacitor terminals 678 may be members of another interconnect level of the microelectronic device 600.

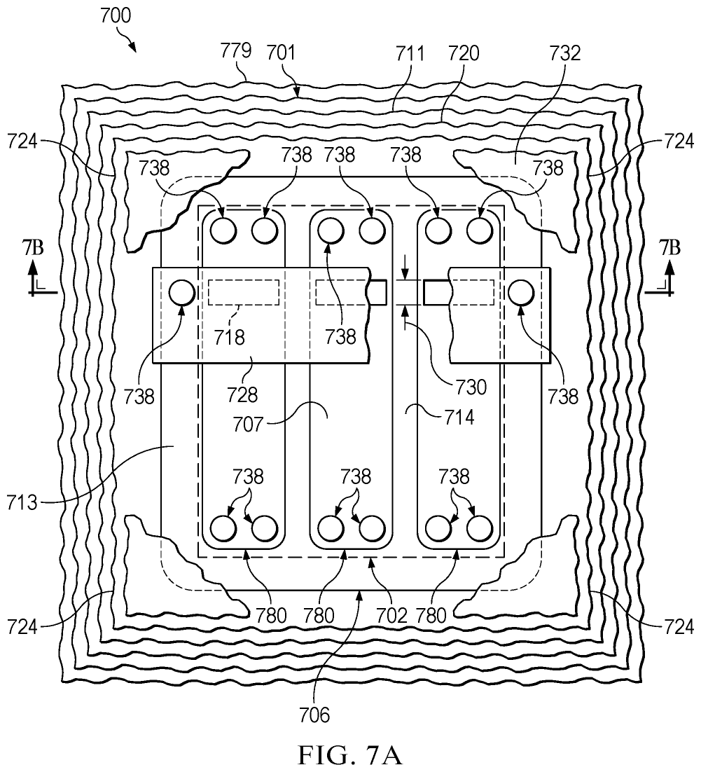

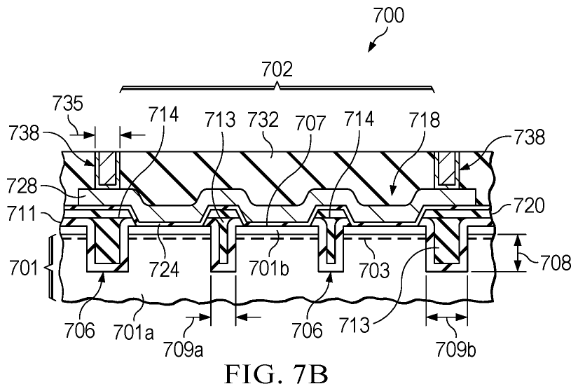

FIG. 7A and FIG. 7B are a top view and a cross section, respectively, of a further example microelectronic device having topological structures in a III-N semiconductor layer. Referring to FIG. 7A and FIG. 7B concurrently, the microelectronic device 700 is formed on a silicon substrate 779. The silicon substrate 779 may have a 111 orientation to facilitate formation of III-N semiconductor material by an epitaxial process. A III-N semiconductor layer 701 is formed on the silicon substrate 779. In this example, the III-N semiconductor layer 701 may include a first III-N semiconductor sublayer 701a, which may be manifested as an undoped layer of gallium nitride, and a second III-N semiconductor sublayer 701b, which may be manifested as a barrier layer, on the first III-N semiconductor sublayer 701a, and which produces a 2DEG 703 in the first III-N semiconductor sublayer 701a, immediately under the second III-N semiconductor sublayer 701b. The III-N semiconductor layer 701 has a top surface 707; the second III-N semiconductor sublayer 701b may extend to the top surface 707, as depicted in FIG. 7B.

A GaN FET 702 is formed in and on the III-N semiconductor layer 701. In this example, the GaN FET 702 includes a plurality of channels 780. The channels 780 are laterally separated by a topological structure 706, which also surrounds the GaN FET 702. The topological structure 706 has a maximum vertical dimension 708 from the top surface 707, extending into the III-N semiconductor layer 701. The microelectronic device 700 includes a liner 711, formed on the top surface 707, extending onto the topological structure 706, contacting the III-N semiconductor layer 701. The liner 711 includes silicon nitride.

The microelectronic device 700 includes a fill material 713, formed on the liner 711, filling the topological structure 706. The fill material 713 is planarized. The fill material 713 may include silicon nitride. A top surface 714 of the fill material 713 is planar, that is, deviations in the top surface 714 are less than 10 percent of the maximum vertical dimension 708 of the topological structure 706. The top surface 714 is parallel to the top surface 707 of the III-N semiconductor layer 701 adjacent to the topological structure 706. In this example, planarization of the fill material 713 may expose portions of the liner 711 outside of the topological structure 706, as depicted in FIG. 7B.

Portions of the topological structure 706 between adjacent channels 780 may have first widths 709a that are significantly less than the maximum vertical dimension 708 of the topological structure 706. These portions of the topological structure 706 provide current confinement in the GaN FET 702. Any potential difference across these portions of the topological structure 706 at any point is significantly less than a potential difference between a source and a drain of the GaN FET 702; thus these portions of the topological structure 706 may be formed as narrowly as practical, consistent with the fabrication processes used to form the microelectronic device 700. Another portion of the topological structure 706, surrounding the GaN FET 702, may be required to isolate a potential difference equal to, or greater than, the potential difference between the source and the drain, and so may have a second width 709b that is comparable to, or greater than, the maximum vertical dimension 708 of the topological structure 706.

A gate field relief layer 720 is formed over the fill material 713 and the liner 711. The gate field relief layer 720 may include silicon nitride or other dielectric material. The gate field relief layer 720 and the liner 711 are patterned, for example by an etch process using a photolithographically formed etch mask, to expose the III-N semiconductor layer 701 in gate recesses 718. A gate dielectric layer 724 is formed over the III-N semiconductor layer 701 in the gate recesses 718, and extending over the liner 711 and the gate field relief layer 720. The gate dielectric layer 724 may include silicon nitride, and may be 50 nanometers to 100 nanometers thick.

A combined gate/field plate 728 is formed over the gate dielectric layer 724, extending into the gate recesses 718. The combined gate/field plate 728 may include metal, such as titanium, titanium tungsten, nickel, or gold, by way of example. The combined gate/field plate 728 may be patterned by a masked etch process. The combined gate/field plate 728 has a gate length 730 that is less than the maximum vertical dimension 708 of the topological structure 706, which is enabled by the planarity of the top surface 714 of the fill material 713. The combined gate/field plate 728 may be formed to extend across the topological structure 706, enabled by the planarity of the fill material 713.

A PMD layer 732 is formed over an existing top surface of the microelectronic device 700, including the combined gate/field plate 728. The PMD layer may include silicon nitride or other dielectric material. The PMD layer 732 may be planarized, for example by a CMP process. Planarization of the PMD layer 732 is advantageously facilitated by the planarity of the top surface 714 of the fill material 713.

Contacts 738 are formed through the PMD layer 732 to provide electrical connections to the combined gate/field plate 728 and to the 2DEG 703 in source and drain regions of the GaN FET 702. The contacts 738 may have lateral dimensions 735 less than a maximum vertical dimension 708 of the topological structures 706, advantageously facilitated by the planarity of the top surface 714.

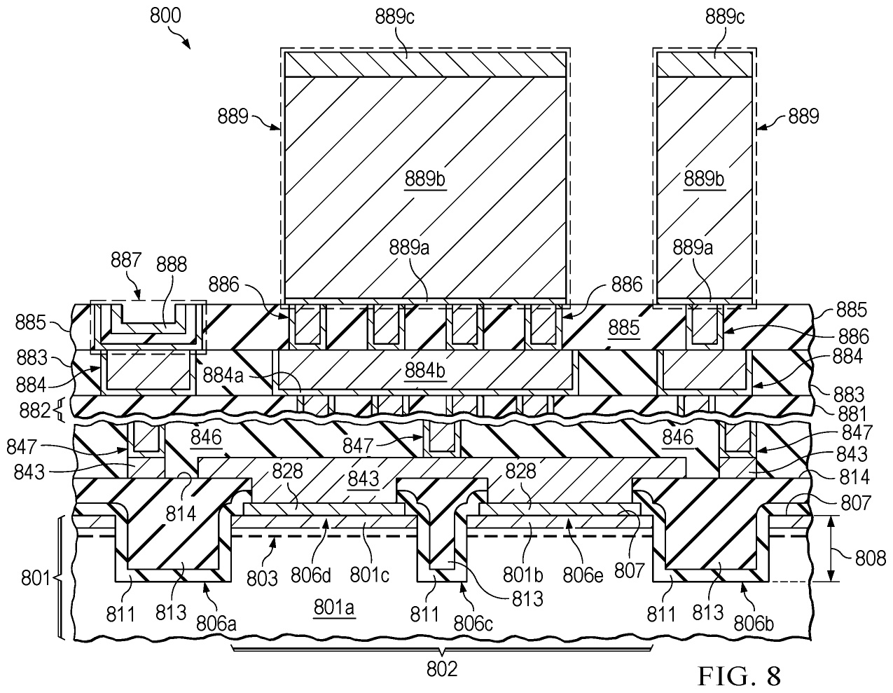

FIG. 8 is a cross section of a further example microelectronic device having topological structures. Referring to FIG. 8, the microelectronic device 800 includes a III-N semiconductor layer 801. A GaN FET 802 is formed in and on the III-N semiconductor layer 801. In this example, the III-N semiconductor layer 801 includes a first III-N semiconductor sublayer 801a, which may be manifested as an undoped layer of gallium nitride. The III-N semiconductor layer 801 of this example includes a second III-N semiconductor sublayer 801b, which may be manifested as a barrier layer on the first III-N semiconductor sublayer 801a. The III-N semiconductor layer 801 of this example further includes a third III-N semiconductor sublayer 801c, which may be manifested as a layer of p type gallium nitride, on the second III-N semiconductor sublayer 801b. The first III-N semiconductor sublayer 801a, the second III-N semiconductor sublayer 801b, and the third III-N semiconductor sublayer 801c may be formed by sequential epitaxial processes. The second III-N semiconductor sublayer 801b produces a 2DEG 803 in the first III-N semiconductor sublayer 801a, immediately under the second III-N semiconductor sublayer 801b.

A first topological structure 806a and a second topological structure 806b are formed in the III-N semiconductor layer 801, adjacent to the GaN FET 802. A third topological structure 806c is formed in the III-N semiconductor layer 801, in an area occupied by the GaN FET 802. The first, second, and third topological structures 806a, 806b, and 806c may be manifested in this example as openings 806a, 806b, and 806c, extending to a top surface 807 of the III-N semiconductor layer 801.

A fourth topological structure 806d and a fifth topological structure 806e are formed in the III-N semiconductor layer 801, in which a portion of the third III-N semiconductor sublayer 801c is removed from the GaN FET 802, leaving remaining portions of the third III-N semiconductor sublayer 801c to provide a gate 828 of the GaN FET 802. The fourth and fifth topological structures 806d and 806e may thus be manifested as protrusions of the III-N semiconductor layer 801.

The top surface 807 of the III-N semiconductor layer 801 extends into the first, second, and third topological structures 806a, 806b, and 806c, and over the fourth and fifth topological structures 806d and 806e, and so the top surface 807 is not planar over the complete III-N semiconductor layer 801. Portions of the top surface 807 of this example are planar, such as the top surface 807 adjacent to each of the topological structures 806a through 806e.

A liner 811 is formed on the top surface 807 of the III-N semiconductor layer 801, extending onto the topological structures 806a, 806b, and 806c, and over the fourth and fifth topological structures 806d and 806e, contacting the III-N semiconductor layer 801. The liner 811 includes silicon nitride.

A fill material 813 is formed on the liner 811 and planarized, filling the topological structures 806a, 806b, and 806c which are manifested as openings in the III-N semiconductor layer 801. The fill material 813 may optionally cover the fourth and fifth topological structures 806d and 806e which are manifested as protrusions of the III-N semiconductor layer 801. The fill material 813 may include silicon nitride. A top surface 814 of the fill material 813 is planar, that is, deviations in the top surface 814 are less than 10 percent of the maximum vertical dimension 808 of the topological structures 806a through 806e. The top surface 814 is parallel to the top surface 807 of the III-N semiconductor layer 801 adjacent to the topological structures 806a through 806e.

Portions of the fill material 813 and the liner 811 are removed to expose the gate 828. First interconnects 843 are formed over the fill material 813. At least one of the first interconnects 843 makes an electrical connection to the gate 828. The first interconnects 843 may have structures and compositions similar to the first interconnects 143 of FIG. 1R. Source and drain regions of the GaN FET 802 are out of the plane of FIG. 8. During operation of the GaN FET 802, current flows in the 2DEG 803 under the gate 828 in a direction perpendicular to the plane of FIG. 8. A gate length of the GaN FET 802 may be less than the maximum vertical dimension 808 of the topological structures 806a through 806e, enabled by the planarity of the top surface 814.

A first ILD layer 846 is formed over the fill material 813 and the first interconnects 843. The first ILD layer 846 includes silicon nitride, silicon dioxide, or other dielectric material. The first ILD layer 846 may be planarized, which may be advantageously facilitated by the planarity of the top surface 814 of the fill material 813.

First vias 847 are formed through the first ILD layer 846 to the first interconnects 843. The first vias 847 may have damascene structures and compositions similar to the contacts 138 of FIG. 1P, enabled by the planarity of the top surface 814.

Formation of the microelectronic device 800 continues with forming a top ILD layer 881 above the first vias 847 and the first ILD layer 846. One more additional levels of interconnects, ILD layers, and vias, not specifically shown may be formed between the first ILD layer 846 and the top ILD layer 881. Upper vias 882 are formed through the top ILD layer 881, making electrical connections to underlying interconnects, not specifically shown.

A top inter-metal dielectric (IMD) layer 883 is formed over the top ILD layer 881 and the upper vias 882. The top IMD layer 883 may include an etch stop sublayer of silicon nitride, a main sublayer of silicon dioxide, and CMP stop layer of silicon nitride, by way of example. Top interconnects 884 are formed in the top IMD layer 883, making electrical connections to the upper vias 882. The top interconnects 884 of this example have a copper damascene structure with a tantalum nitride liner 884a and a copper fill metal 884b. The top interconnects 884 are formed by a copper damascene process, enabled by the planarity of the fill material 813.

A protective overcoat (PO) layer 885 is formed over the top IMD layer 883 and the top interconnects 884. The PO layer 885 may include a plurality of sublayers of dielectric material, such as silicon dioxide, silicon nitride, and silicon oxynitride. The PO layer 885 may be formed by sequential PECVD processes, by way of example. Top vias 886 and a probe pad 887 are formed through the PO layer 885, making electrical connections to the top interconnects 884. The top vias 886 have a tungsten damascene structure, similar to the upper vias 882. The probe pad 887 is formed by sequential damascene processes. A portion of the probe pad 887 may be formed concurrently with the top vias 886. The probe pad 887 is significantly wider than each of the top vias 886, so that the liner and fill metal used to form the top vias 886 do not fill the opening in the PO layer 885 for the probe pad 887. One or more additional layers of pad metal 888 may be formed over the PO layer 885, extending into the opening for the probe pad 887, onto the liner and fill metal already in the opening. The additional layers of pad metal 888 are removed from over the PO layer 885 outside of the probe pad 887 by a metal CMP process. The damascene processes to form the top vias 886 and the probe pad 887 are enabled by the planarity of the fill material 813.

Bump bond pillars 889 are formed over the PO layer 885, making electrical connections to the top vias 886. The bump bond pillars 889 may be 3 microns to 30 microns high, by way of example. Each of the bump bond pillars 889 may include a seed layer 889a, a copper pillar 889b on the seed layer 889a, and a barrier cap 889c on the copper pillar 889b. The seed layer 889a may include an adhesion layer including titanium, and a plating layer containing copper. The copper pillar 889b includes essentially copper, optionally with some trace materials. The barrier cap 889c includes metals to facilitate solderability while blocking tin from the copper pillar 889b. The barrier cap 889c may include nickel, palladium, or other refractory metals, by way of example. The seed layer 889a may be formed by successive physical vapor deposition (PVD) processes across the PO layer 885, making electrical connections to the top vias 886. After the seed layer 889a is formed, a plating mask, not specifically shown, is formed over the seed layer 889a, exposing the seed layer 889a in areas for the bump bond pillars 889. The plating mask may include photoresist, formed by a photolithographic process, enabled by planarity of the fill layer 813, which provides adequate depth of focus across the microelectronic device 800. The copper pillars 889b are formed on the seed layer 889a by a copper electroplating process. The barrier caps 889c are formed by one or mode subsequent electroplating processes. After the barrier caps 889c are formed, the plating mask is removed. Subsequently, the seed layer 889a outside of the bump bond pillars 889 is removed by a wet etch process. Separate instances of the bump bond pillars 889 may have different lateral dimensions, appropriate for different currents through the bump bond pillars 889 during operation of the microelectronic device 800. Tops of the bump bond pillars 889 are essentially coplanar, that is, differences in planarity of the tops of the bump bond pillars 889 are less than the maximum vertical dimension 808 of the topological structures 806a through 806e, which may provide improved reliability of subsequently formed solder joints on the bump bond pillars 889. The coplanarity of the tops of the bump bond pillars 889 are enabled by planarity of the fill layer 813, which provides a planar top surface of the PO layer 885.

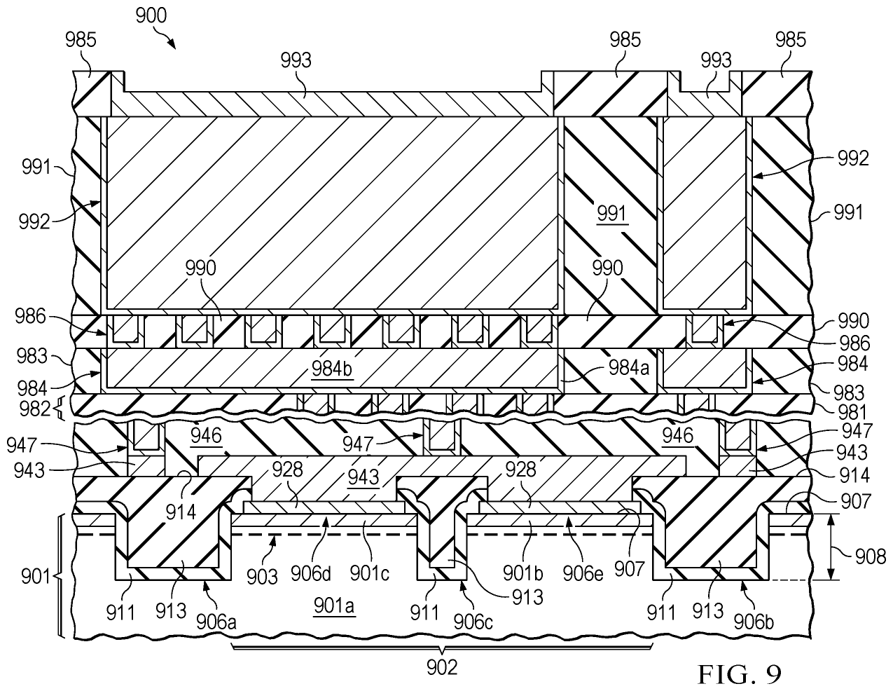

FIG. 9 is a cross section of a further example microelectronic device having topological structures. Referring to FIG. 9, the microelectronic device 900 includes a III-N semiconductor layer 901 having a first III-N semiconductor sublayer 901a, a second III-N semiconductor sublayer 901b, and a third III-N semiconductor sublayer 901c, similar to the III-N semiconductor layer 801 of FIG. 8. A GaN FET 902 is formed in and on the III-N semiconductor layer 901. The second III-N semiconductor sublayer 901b produces a 2DEG 903 in the first III-N semiconductor sublayer 901a, immediately under the second III-N semiconductor sublayer 901b.

The microelectronic device 900 includes a first topological structure 906a and a second topological structure 906b in the III-N semiconductor layer 901, on opposite sides of the GaN FET 902, and includes a third topological structure 906c in the III-N semiconductor layer 901, between the first topological structure 906a and the second topological structure 906b, manifested in this example as openings 906a, 906b, and 906c, of the III-N semiconductor layer 901.

The microelectronic device 900 includes a fourth topological structure 906d and a fifth topological structure 906e in the III-N semiconductor layer 901, manifested as protrusions of the III-N semiconductor layer 901. The fourth and fifth topological structures 906d and 906e provide a gate 928 of the GaN FET 902.

The III-N semiconductor layer 901 has a top surface 907 which extends into the first, second, and third topological structures 906a, 906b, and 906c, and over the fourth and fifth topological structures 906d and 906e. The top surface 907 of this example is not planar over the complete III-N semiconductor layer 901. Portions of the top surface 907 of this example are planar, such as the top surface 907 adjacent to each of the topological structures 906a through 906e.

The microelectronic device 900 includes a liner 911, which includes silicon nitride, formed on the top surface 907 of the III-N semiconductor layer 901, contacting the III-N semiconductor layer 901, and extending onto the topological structures 906a, 906b, and 906c, and over the fourth and fifth topological structures 906d and 906e.

The microelectronic device 900 includes a fill material 913, which may include silicon nitride, formed on the liner 911 and planarized, filling the topological structures which are manifested as openings in the III-N semiconductor layer 901, that is topological structures 906a, 906b, and 906c. A top surface 914 of the fill material 913 is planar, that is, deviations in the top surface 914 are less than 10 percent of the maximum vertical dimension 908 of the topological structures 906a through 906e. The top surface 914 is parallel to the top surface 907 of the III-N semiconductor layer 901 adjacent to the topological structures 906a through 906e.

The microelectronic device 900 includes first interconnects 943, including aluminum or other metal, formed over the fill material 913. At least one of the first interconnects 943 extends through the fill material 913 and the liner 911 to make an electrical connection to the gate 928. Source and drain regions of the GaN FET 902 are out of the plane of FIG. 9. A gate length of the GaN FET 902 may be less than the maximum vertical dimension 908 of the topological structures 906a through 906e, enabled by the planarity of the top surface 914.

The microelectronic device 900 includes a first ILD layer 946 over the fill material 913 and the first interconnects 943, first vias 947 through the first ILD layer 946 to the first interconnects 943, an upper ILD layer 981 above the first vias 947 and the first ILD layer 946, upper vias 982 through the upper ILD layer 981, an upper IMD layer 983 over the upper ILD layer 981 and the upper vias 982, and top interconnects 984 in the upper IMD layer 983, making electrical connections to the upper vias 982. The first ILD layer 946, the first vias 947, the upper ILD layer 981, the upper vias 982, the upper IMD layer 983, and the top interconnects 984 may be formed as described in reference to the corresponding elements of FIG. 8, and may have similar compositions ad structures.

The microelectronic device 900 of this example includes a top ILD layer 990, including silicon dioxide. The microelectronic device 900 of this example further includes top vias 986 having a tungsten damascene structure and formed by a tungsten damascene process, through the top ILD layer 990, making electrical connections to the underlying top interconnects 984.

The microelectronic device 900 of this example includes a top IMD layer 991 formed over the top ILD layer 990 and the top vias 986. The top IMD layer 991 includes an etch stop sublayer of silicon nitride or silicon carbonitride, on the upper IMD layer 983, a main sublayer of silicon dioxide over the etch stop sublayer, and a CMP stop layer of silicon nitride or silicon carbonitride, over the main sublayer. The etch stop sublayer, the main sublayer, and the CMP stop layer are not specifically shown.

Copper bump pillars 992 are formed through the top IMD layer 991 by a copper damascene process, making electrical connections to the top vias 986. Forming the copper bump pillars 992 by the copper damascene process advantageously enables a closer spacing compared to plated pillars, as there is no plating mask to remove. The top IMD layer 991 may advantageously provide mechanical support for the copper bump pillars 992 during a subsequent solder bump process.

A PO layer 985 is formed over the top IMD layer 991 and the copper bump pillars 992. The PO layer 985 of this example includes an etch stop sublayer of silicon nitride, formed over the top IMD layer 991 and the copper bump pillars 992. PO layer 985 of this example further includes a first moisture barrier sublayer of silicon dioxide, formed over the etch stop sublayer, and a second moisture barrier sublayer of silicon oxynitride, formed over the first moisture barrier sublayer. The etch stop sublayer and the first and second moisture barrier sublayers are not specifically shown. The PO layer 985 of this example may be 1 micron to 3 microns thick, by way of example.

Barrier caps 993 are formed through the PO layer 985, making electrical connections to the copper bump pillars 992. The barrier caps 993 are formed by forming barrier via holes through the PO layer 985, exposing tops of the copper bump pillars 992. One or more sublayers of barrier metals, such as titanium, nickel, cobalt, copper, palladium, or gold, are formed by sequential PVD processes on the PO layer 985, extending into the barrier via holes onto the tops of the copper bump pillars 992. The sublayers of metals are removed from over the PO layer 985 by one or more metal CMP processes, leaving the sublayers of barrier metals in the barrier via holes to provide the barrier caps 993. Forming the barrier caps 993 using the one or more metal CMP processes may advantageously enable thinner barrier caps 993 compared to plating on the copper bump pillars 992, providing less stress between the barrier caps 993 and the copper bump pillars 992. The one or more metal CMP processes are enabled by the planarity of the top surface 914.

Various features of the examples disclosed herein may be combined in other manifestations of example microelectronic devices. For example, any the microelectronic devices 100, 200, 500, 600, 700, 800, and 900 may include topological structures that are manifested as openings in the corresponding III-N semiconductor layers 101, 201, 501, 601, 701, 801, and 901. Any of the microelectronic devices 100, 200, 500, 600, 700, 800, and 900 may include topological structures that are manifested as protrusions of the corresponding III-N semiconductor layers 101, 201, 501, 601, 701, 801, and 901. Any of the microelectronic devices 100, 200, 500, 600, 700, 800, and 900 may include a GaN FET having a gate length less than a maximum vertical dimension of the topological structure or structures in the corresponding microelectronic device. Any of the microelectronic devices 100, 200, 500, 600, 700, 800, and 900 may include a conductor above a topological feature, wherein the conductor has a lateral dimension less than a maximum vertical dimension of the topological structure. Any of the microelectronic devices 100, 200, 500, 600, 700, 800, and 900 may include contacts or vias having damascene structures with lateral dimensions less than a maximum vertical dimension of topological structures in the microelectronic device. Any of the microelectronic devices 100, 200, 500, 600, 700, 800, and 900 may include a thin film resistor, an MIM capacitor, or a galvanic isolation component.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a III-N semiconductor layer having a top surface;
a topological structure of the III-N semiconductor layer;
a liner on the topological structure contacting the III-N semiconductor layer, the liner including silicon nitride; and
a fill material in the topological structure on the liner, the fill material including dielectric material, wherein a top surface of the fill material is planar and parallel to the top surface of the III-N semiconductor layer adjacent to the topological structure.

2. The microelectronic device of claim 1, wherein the topological structure is an opening in the III-N semiconductor layer.

3. The microelectronic device of claim 1, wherein a maximum vertical dimension of the topological structure is greater than a lateral dimension of the topological structure.

4. The microelectronic device of claim 1, wherein sidewalls of the topological structure are perpendicular to the top surface of the III-N semiconductor layer, within 10 degrees.

5. The microelectronic device of claim 1, wherein the microelectronic device includes a field effect transistor in the III-N semiconductor layer having a gate length less than a maximum vertical dimension of the topological structure.

6. The microelectronic device of claim 1, wherein the fill material includes primarily silicon nitride.

7. The microelectronic device of claim 1, further including a conductive member above the topological structure over the fill material, wherein a width of the conductive member over the topological structure is less than a maximum vertical dimension of the topological structure.

8. The microelectronic device of claim 1, further including;
an inter-level dielectric (ILD) layer above the topological structure over the fill material, wherein a top surface of the ILD layer is planar; and
a conductive member above the topological structure over the ILD layer.

9. The microelectronic device of claim 1, further including a vertical interconnect element, including:
a liner layer extending into a hole through a dielectric layer for the vertical interconnect element, contacting the dielectric layer in the hole; and
a fill metal on the liner layer.

10. The microelectronic device of claim 1, further including a passive component above the topological structure over the fill material.

11. The microelectronic device of claim 1, further including a galvanic isolation component above the topological structure over the fill material.

12. A method of forming a microelectronic device, comprising:
forming a topological structure of a III-N semiconductor layer, the III-N semiconductor layer having a top surface;
forming a liner on the topological structure, contacting the III-N semiconductor layer;
forming a fill material on the liner; and
planarizing the fill material, so that a top surface of the fill material is planar and parallel to the top surface of the III-N semiconductor layer adjacent to the topological structure.

13. The method of claim 12, wherein forming the liner includes forming silicon nitride by a low pressure chemical vapor deposition (LPCVD) process.

14. The method of claim 12, wherein forming the fill material includes forming silicon nitride by a plasma enhanced chemical vapor deposition (PECVD) process.

15. The method of claim 12, wherein planarizing the fill material includes removing at least a portion of the fill material from above the top surface of the III-N semiconductor layer by a chemical mechanical polish (CMP) process.

16. The method of claim 12, further including forming a conductive member above the topological structure over the fill material.

17. The method of claim 16, wherein forming the conductive member includes:
forming a conductive layer; and
forming an etch mask over the conductive layer covering an area for the conductive member, the etch mask having a width less than a maximum vertical dimension of the topological structure, above the topological structure.

18. The method of claim 12, further including forming an ILD layer above the topological structure over the fill material, wherein a top surface of the ILD layer is planar.

19. The method of claim 18, further including forming a conductive member above the topological structure over the ILD layer, the conductive member having a width less than a maximum vertical dimension of the topological structure, above the topological structure.

20. The method of claim 12, further including forming a vertical interconnect element by a process including:
forming a hole for the vertical interconnect element through a dielectric material;
forming a liner layer extending into the hole, the liner layer being electrically conductive;
forming a fill layer on the liner layer, the fill layer being electrically conductive; and
removing the liner layer and the fill layer from over the dielectric material adjacent to the hole.

21. A multi-chip module, comprising:
a first device, including:
a III-N semiconductor layer having a top surface;
a topological structure of the III-N semiconductor layer extending to the top surface of the III-N semiconductor layer;
a liner in the topological structure contacting the III-N semiconductor layer;
a fill material in the topological structure on the liner, wherein a top surface of the fill material is planar and parallel to the top surface of the III-N semiconductor layer adjacent to the topological structure; and
a galvanic isolation component located over the topological structure, a first isolation element of the galvanic isolation component being connected to a component in the III-N semiconductor layer;
a second device, including:
a silicon substrate; and
an active component in the silicon substrate; and
electrical connections between the active component and a second isolation element of the galvanic isolation component.
